(19) United States
(12) Patent Application Publication
(10) Pub. No.: US 2025/0372939 A1
(43) Pub. Date: Dec. 4, 2025

(54) Surface Emitting Laser, Method for Fabricating Surface Emitting Laser

(71) Applicant: SANOH INDUSTRIAL CO., LTD., Tokyo (JP)

(72) Inventor: Srinivas Gandrothula, Koga-shi, Ibaraki (JP)

(21) Appl. No.: 18/870,824

(22) PCT Filed: May 31, 2022
(86) PCT No.: PCT/JP2022/022192

§ 371 Date: Dec. 2, 2024

(51) Int. Cl. H01S 5/02; H01S 5/183

(52) U.S. Cl. CPC H01S 5/0206; H01S 5/18361

(57) ABSTRACT

A vertical cavity surface emitting laser includes an oxide substrate having a first face and a second face at an opposite side from the first face; a semiconductor section disposed on the first face; a dielectric filter layer disposed between the semiconductor section and the first face and having a reflective spectrum configured to provide an optical window; a first DBR mirror; and a second DBR mirror disposed at a curved surface of the second face. The first DBR mirror, the semiconductor section, the dielectric filter layer, the oxide substrate, and the second DBR mirror are arranged in a first axial direction to form an extended cavity. The semiconductor section is disposed between the dielectric filter layer and the first DBR mirror, and includes a p-type III nitride region, an n-type III nitride region, and a III nitride active region between the p-type and n-type III nitride regions.

### TECHNICAL FIELD

This invention relates to an extended cavity III nitride vertical cavity surface emitting laser (VCSEL) and a method for fabricating an extended cavity III nitride VCSEL.

### BACKGROUND ART

Surface emitting lasers are known as vertical cavity surface emitting lasers (VCSELs). A VCSEL comprises a semiconductor active region disposed between an n-side semiconductor region and a p-side semiconductor region, and two distributed Bragg reflectors, which are referred to as DBRs, acting as high reflective mirrors. The semiconductor active region, also known as a gain medium, is disposed between the two DBRs such that the two DBRs and the semiconductor active region form an optical cavity. The n-side and p-side regions inject respective carriers, i.e., electron and hole, to the active region, and these carriers recombine in the active region to generate light. The light or electromagnetic radiation thus generated is reflected a number of times by the DBRs to travel in the optical cavity, leading to lasing. The VCSEL provides one of the DBRs with a less reflectance mirror, which is used to emit the laser beam.

This application references a number of patent or non-patent publications as indicated throughout the specification by their reference numbers within brackets, i.e. [ ]. The list of the publications ordered according to these reference numbers can be found below in the section entitled “Non Patent Literature” or “Patent literature”.

### PRIOR ART DOCUMENT

### Non-Patent Literature

| | |
|---|---|
| NPL 1 | Appl. Phys. Express 12, 044004 (2019) |
| NPL 2 | Sci. Rep. 8, 10350 (2018) |
| NPL 3 | Applied Phys. Lett. 83, 2121 (2003) |
| NPL 4 | Appl. Phys. Express 2008, 1, 121102. |
| NPL 5 | Appl. Phys. Express 2012, 5, 092104 |
| NPL 6 | Optics Express, 27, 24717 (2019) |
| NPL 7 | Appl. Phys. Express, 13, 041003 (2020) |
| NPL 8 | Appl. Phys. Express, 14,031002 (2021) |
| NPL 9 | Applied Phys. Lett. 119, 142103 (2021) |
| NPL 10 | Crystals, 11 (12) 1563, (2021) |
| NPL 11 | M. B. Stern and T. R. Jay, “Dry etching |
| | for coherent refractive micro-lens arrays,” |
| | Opt. Eng. 33, 3547-3551 (1994) |

### SUMMARY OF INVENTION

### Technical Problem

An optical cavity defined by two planar DBR mirrors in a VCSEL suffers an excessive diffraction loss with increasing the cavity length. Using a curved mirror or lens in a VCSEL allows the VCSEL to have a long optical cavity. As shown in Refs. [NPL1] and [NPL2], the curved mirror or lens focuses the electric field of lasing light into the gain medium to reduce the diffraction loss that originate from the longer cavity length. Tailoring the cavity mode to align with the gain spectrum in a VCSEL can achieve a high efficient operation. Using a very short cavity length, for example, one or two lasing wavelengths in a VCSEL makes the spacing of the cavity modes large. Due to the large spacing, it is less likely that at least one of the cavity modes to fall within the gain spectrum of the VCSEL, thereby decreasing the yield and lasing efficiency of the VCSEL. In contrast, increasing the cavity length makes the mode spacing narrow. Due to the narrow spacing, it is highly probable that one of the cavity modes falls within the gain spectrum of the VCSEL, thereby enhancing the yield of lasing.

However, in a VCSEL having a long cavity, it is a challenging task that all of the device layers except for the active region are made of materials transparent to the electromagnetic radiation that propagates in the VCSEL. One of the DBR mirrors can be disposed on the curved back side of the semiconductor host substrate of III nitride, which is formed as a lens structure. Accordingly, the VCSEL of this structure does not use the substrate removal, which results in that the III nitride host substrate may introduce moderate losses in the cavity. This curved mirror approach, which is proposed in Refs. [NPL 1] and [NPL 2], still provides the cavity with a significant portion of the native host substrate, where the lens structure is formed by etching to formulate the curved n-side DBR mirror thereon. This approach is designed for homo-epitaxy of GaN. Additionally, the dopant concentration of the host substrate included in the long cavity should be as low as the level of the loss of pin absorption. Accordingly, the host substrate is first thinned to reduce optical absorption loss in the cavity. Thinning the substrate can be a difficult process to control in thickness, and may damage the substrate because the substrate has to be thinned from an initial thickness of 300 to 400 micrometers to a target thickness of 10 to 30 micrometers to provide the VCSEL with a desired cavity length.

Otherwise, the inclusion of the host substrate in the cavity may cause an unintentional-absorption loss for every round trip of the electromagnetic radiation, thereby preventing the lasing threshold from lowering. However, the author of Ref. [NPL 3] demonstrates the operation of a GaN-based VCSEL in an extended cavity scheme, which is fabricated by directly growing GaN-based device layers on a less-absorption sapphire substrate. In such a scheme, the lattice mismatch between the sapphire substrate and the device layers still restrict the crystalline quality of the device layers, and accordingly, the lifetime and yield of such devices would be problematic.

It would be preferred that the absorption source be kept as thin as possible while keeping a stable laser operation and that the bottom mirror have to be positioned to form the cavity with the top and bottom mirrors being located close to each other, which results in removal of the native substrate. In a hetero-epitaxy approach, III nitride device layers are grown on a hetero-substrate, such as sapphire or silicon, and the hetero-substrate of the III nitride VCESL device can be easily removed by chemical etching or laser lift-off (referred to as “LLO”) as in Ref. [NPL 4], while the hetero-epitaxy of GaN on sapphire substrates cannot enhance its crystalline quality. However, conventional LLO processes are not acceptable to GaN homo-epitaxy. In other approaches, the removal of III nitride device layers from a GaN homo-epitaxy structure is reported in Ref. [NPL 5], and is still very interesting as in Refs. [NPL 6] to [NPL 10].

The longer the cavity becomes, the better the stability becomes in terms of lasing as well as thermal drift. Alternatively, an extended cavity VCSEL design can be realized by carefully removing VCSEL device layers from the native growth substrate or hetero substrate, and then reattaching a lossless transparent oxide (referred to as “TO”) materials, such as ZnO and group-III oxide, where the group-III oxide may include Al₂O₃ and Ga₂O₃. This design requires the surface preparation that must be achieved below sub-nanometer level in both of the attaching TO substrate and the removed device layers, and causes a potentially unwanted reflection due to the refractive index difference at the GaN/Oxide interface thus formed by reattaching. If this reflection leads to degradation in device performance, the unwanted reflection may be suppressed by an antireflection coating at the interface. All of these procedures are time consuming, and lead to raining issues regarding additional cost.

Considering all these disadvantages, it is an object of the present disclosure to provide the structure of a III VCSEL with an extended cavity feature and a method for fabricating a VCSEL with an extended cavity feature. It is another object of the present disclosure to provide a single-step integration solution allowing the formation of an extended cavity without involving complex bonding and substrate removal procedures.

### Solution to Problem

One configuration of the present disclosure is a VCSEL, which comprises: an oxide substrate having a first face and a second face at an opposite side from the first face, the second face including a curved surface; a semiconductor section disposed on the first face of the oxide substrate; a dielectric filter layer disposed between the semiconductor section and the first face of the oxide substrate and having a reflective spectrum, the reflective spectrum being configured to provide an optical window; a first distributed Bragg reflector (DBR) mirror, the semiconductor section being disposed between the dielectric filter layer and the first DBR mirror; and a second DBR mirror disposed at the curved surface of the oxide substrate, the first DBR mirror, the semiconductor section, the dielectric filter layer, the oxide substrate, and the second DBR mirror being arranged in a first axial direction to form an extended cavity, the semiconductor section including a p-type III nitride region, a III nitride region, and a III nitride active region between the p-type III nitride region and the III nitride region, the p-type III nitride region, the III nitride active region, and the III nitride region being arranged in the first axial direction, and the III nitride region including an n-type III nitride region.

Another configuration of the present disclosure is a method for fabricating a VCSEL, and the method comprises: preparing a starting base, the starting base including an oxide base, a III nitride template plug, and a dielectric filter layer, the oxide base having a first face and a second face at an opposite side from the first face of the oxide base, the dielectric filter layer and the III nitride template plug being located on the first face of the oxide base, the dielectric filter layer having a reflective spectrum, and the reflective spectrum being configured to provide an optical window; growing a III nitride region from the III nitride template plug on the dielectric filter layer; after growing the III nitride region, growing a semiconductor laminate including an n-type III nitride region, a III nitride active region, and a p-type III nitride region; processing the oxide base at the second face thereof to form an oxide substrate having a curved surface, the curved surface being disposed at an opposite side from a first face of the oxide substrate; after growing the semiconductor laminate, forming a first distributed Bragg reflector (DBR) laminate on the first face of the oxide substrate; and forming a second DBR laminate on the curved surface of the oxide substrate.

### Advantageous Effects of Invention

The above configurations can provide the structure of a III VCSEL with an extended cavity feature and a method for fabricating a VCSEL with an extended cavity feature.

### BRIEF DESCRIPTION OF DRAWINGS

FIG. 1 is a schematic cross-sectional view showing an extended cavity VCSEL, which includes two mirrors and one Fabry-Perot filter, according to one embodiment of the present disclosure.

FIG. 2 is a schematic top view showing the VCSEL according to the embodiment of the present disclosure.

FIG. 3A is a schematic view showing a process step in a method for fabricating an extended cavity VCSEL according to an embodiment of the present disclosure.

FIG. 3B is a schematic view showing a process step in the VCSEL fabrication method according to the present embodiment.

FIG. 3C is a schematic view showing a process step in the VCSEL fabrication method according to the present embodiment.

FIG. 3D is a schematic view showing a process step in the VCSEL fabrication method according to the present embodiment.

FIG. 3E is a schematic view showing a process step in the VCSEL fabrication method according to the present embodiment.

FIG. 3F is a schematic view showing a process step in the VCSEL fabrication method according to the present embodiment.

FIG. 3G is a schematic view showing a process step in the VCSEL fabrication method according to the present embodiment.

FIG. 3H is a schematic view showing a process step in the VCSEL fabrication method according to the present embodiment.

FIG. 3I is a schematic view showing a process step in the VCSEL fabrication method according to the present embodiment.

FIG. 3J is a schematic view showing a process step in the VCSEL fabrication method according to the present embodiment.

FIG. 3K is a schematic view showing a process step in the VCSEL fabrication method according to the present embodiment.

FIG. 3L is a schematic view showing a process step in the VCSEL fabrication method according to the present embodiment.

FIG. 3M is a schematic view showing a process step in the VCSEL fabrication method according to the present embodiment.

FIG. 3N is a schematic view showing a process step in the VCSEL fabrication method according to the present embodiment.

FIG. 3O is a schematic view showing a process step in the VCSEL fabrication method according to the present embodiment.

FIG. 3P is a schematic view showing a process step in the VCSEL fabrication method according to the present embodiment.

FIG. 3Q is a schematic view showing a process step in the VCSEL fabrication method according to the present embodiment.

FIG. 3R is a schematic view showing a process step in the VCSEL fabrication method according to the present embodiment.

FIG. 4A is a schematic perspective view showing the major elements of a VCSEL product which is fabricated according to the fabrication method according to the present embodiment.

FIG. 4B is a schematic top view showing the major elements of the VCSEL product according to the present embodiment.

FIG. 5 is a schematic top view showing one arrangement of the device sections in the VCSEL product in the VCSEL fabrication method according to the present embodiment.

FIG. 6 is a schematic top view showing another arrangement of the device sections in the VCSEL product in the VCSEL fabrication method according to the present embodiment.

FIG. 7 is a schematic top view showing still another arrangement of the device sections in the VCSEL product in the VCSEL fabrication method according to the present embodiment.

FIG. 8 is a schematic cross sectional view showing an exemplary device structure of the VCSEL according to the present embodiment.

FIG. 9 is a schematic cross sectional view showing an exemplary device structure of the VCSEL according to the present embodiment.

FIG. 10 is a schematic cross sectional view showing an exemplary device structure of the VCSEL according to the present embodiment.

### DESCRIPTION OF EMBODIMENTS

Teachings of the present disclosure can be readily understood by considering the following detailed description with reference to the accompanying drawings shown as examples. Referring to the accompanying drawings, a schematic view showing a vertical cavity surface emitting laser (VCSEL), and a method for fabricating a VCSEL according to the present disclosure will be described below. To facilitate understanding, identical reference numerals are used, where possible, to designate identical elements that are common to the figures.

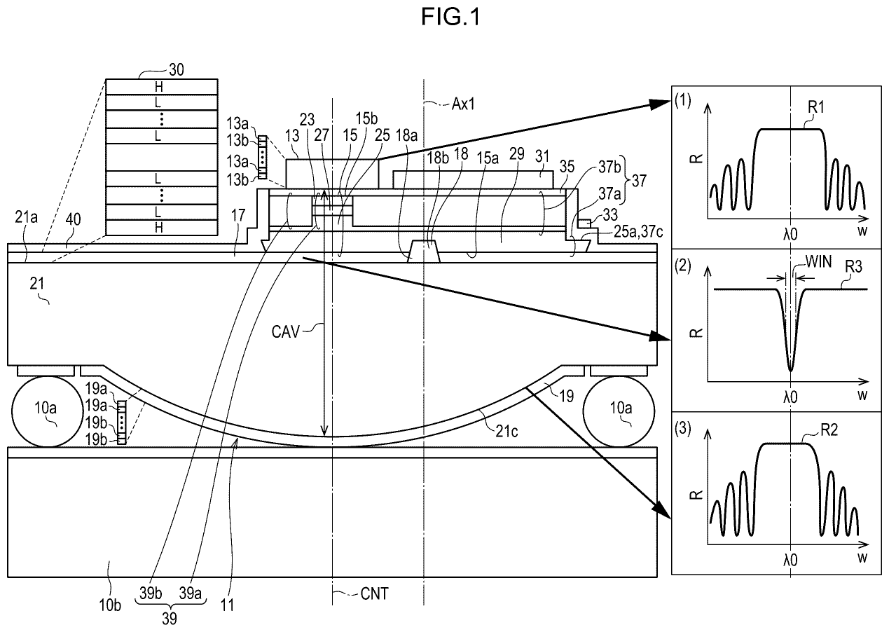

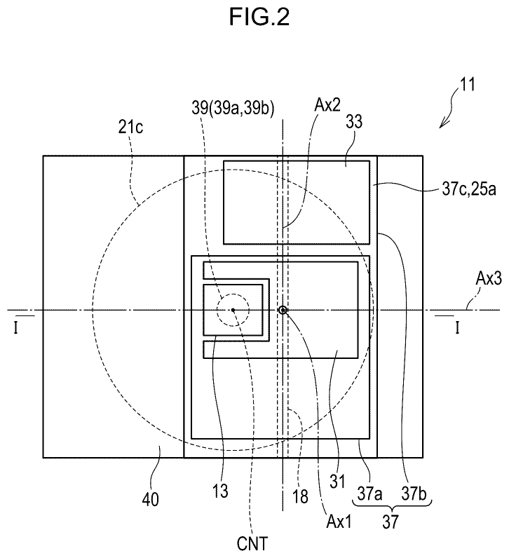

FIG. 1 is a schematic view showing a layer structure of a VCSEL according to the present embodiment. FIG. 2 is a schematic top view showing the VCSEL according to the present embodiment. Specifically, FIG. 1 shows the cross-section taken along line I-I in FIG. 2. FIGS. 1 and 2 show a VCSEL 11, which is bonded to a sub-mount 10a on the curved DBR side of the VCSEL 11 using solder bumps 10b. In each of Portions (1), (2) and (3) of FIG. 1, the vertical axis indicates reflectivity (R), and the horizontal axis indicates wavelength (W).

The VCSEL 11 comprises a first distributed Bragg reflector (DBR) mirror 13, a semiconductor section 15, a dielectric filter layer 17, a second DBR mirror 19, and an oxide substrate 21. The dielectric filter layer 17 is disposed between the first DBR mirror 13 and the second DBR mirror 19. The oxide substrate 21 has a first face 21a and a second face 21b at an opposite side from the first face 21a, and the second face 21b includes a curved surface 21c. The semiconductor section 15 is disposed on the first face 21a of the oxide substrate 21, and is located between the first DBR mirror 13 and the dielectric filter layer 17. The first DBR mirror 13, the semiconductor section 15, the dielectric filter layer 17, the oxide substrate 21, and the second DBR mirror 19 are arranged in the first axial direction Ax1 to form an extended optical cavity CAV. The first DBR mirror 13 is disposed on the semiconductor section 15, and the second DBR mirror 19 is disposed at the curved surface 21c of the oxide substrate 21. The dielectric filter layer 17 is disposed in the extended optical cavity CAV, which is formed by the first DBR mirror 13 and the second DBR mirror 19, and has reflection wavelength regions and an optical window WIN, defined by these reflection wavelength regions, to act as a band pass filter around a wavelength of λ0. The optical window WIN allows a light beam to travel in the optical cavity CAV at a lasing wavelength, and the reflection wavelength regions can block light of wavelengths outside the optical window WIN.

The semiconductor section 15 includes a p-type III nitride region 23, a III nitride active region 27, and a III nitride region 29, and the III nitride region 29 includes an n-type III nitride region 25. The III nitride active region 27 is disposed between the p-type III nitride region 23 and the III nitride region 29 (n-type III nitride region 25). The p-type III nitride region 23, the III nitride active region 27, and the III nitride region 29 (n-type III nitride region 25) are arranged in the first axial direction Ax1. In the VCSEL 11, III nitrides can encompass any compound of nitrogen and group III-element, such as aluminum, gallium, and indium, and specifically, binary alloy, such as gallium nitride (GaN), aluminum nitride (AlN), and indium nitride (InN); ternary alloy, such as gallium aluminum nitride (GaAlN), indium aluminum nitride (InAlN), and gallium indium nitride (GaInN), and quarternary alloy, such as indium gallium aluminum nitride (InGaAlN), which may include any of minor impurities. The III nitrides may be doped with p-type dopant, such as magnesium, carbon and beryllium, to form a p-type region, and may be doped with n-type dopant, such as silicon and tellurium, to form an n-type region. The III nitrides may also be doped with both of p-type and n-type dopants.

The oxide substrate 21 includes one or more oxide materials, and specifically, one of aluminum oxide, for example, Al₂O₃, the bandgap of which is about 8.8 electron volts (eV), zinc oxide, for example, ZnO, the bandgap of which is about 3.37 eV, or gallium oxide, for example, Ga₂O₃, the bandgap of which is about 4.6 to 4.7 eV. These oxide materials, such as aluminum oxide, zinc oxide, and gallium oxide, are transparent to light in visible, infrared or ultraviolet wavelengths, which can pass through the oxide substrate 21.

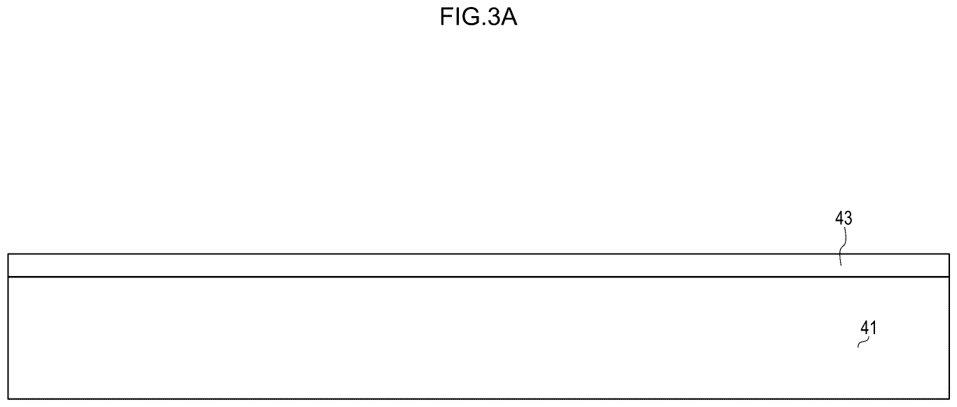

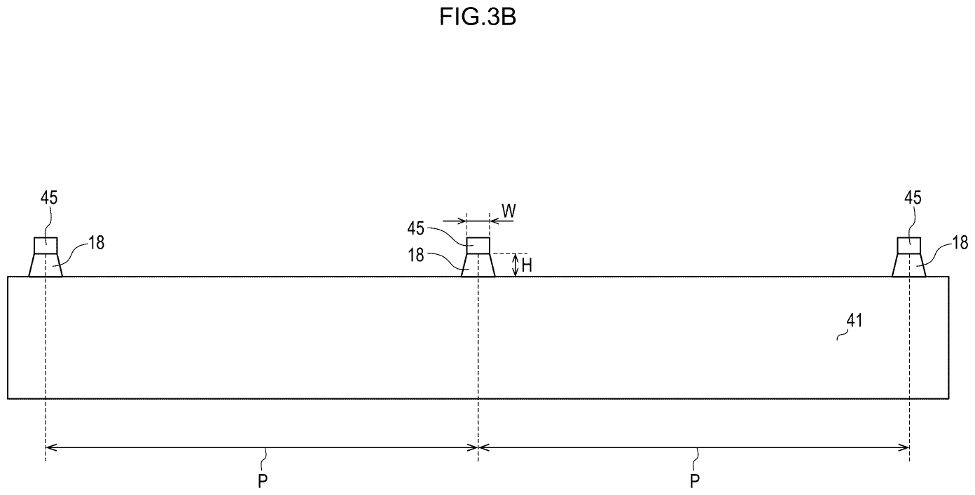

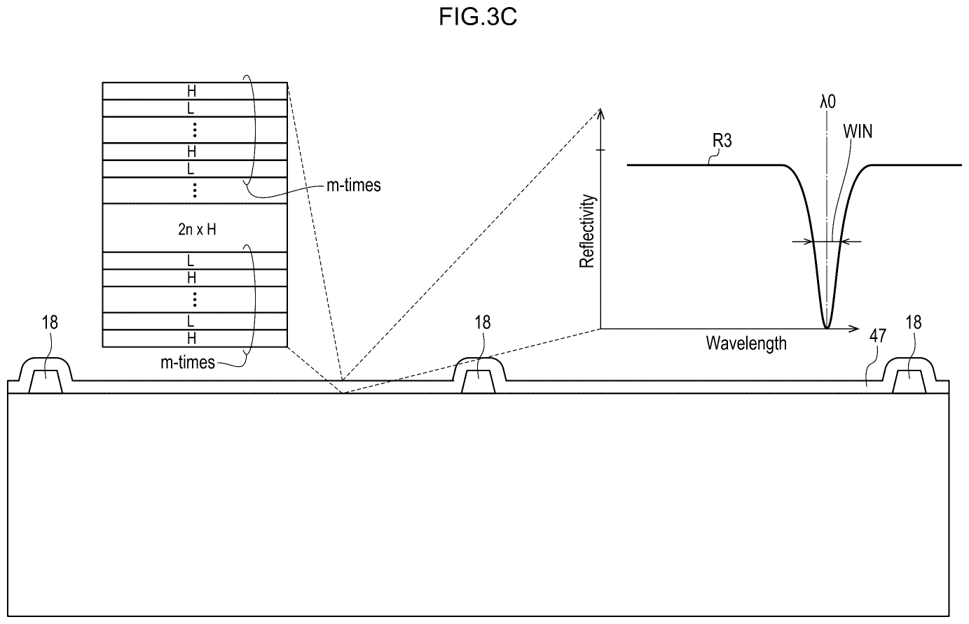

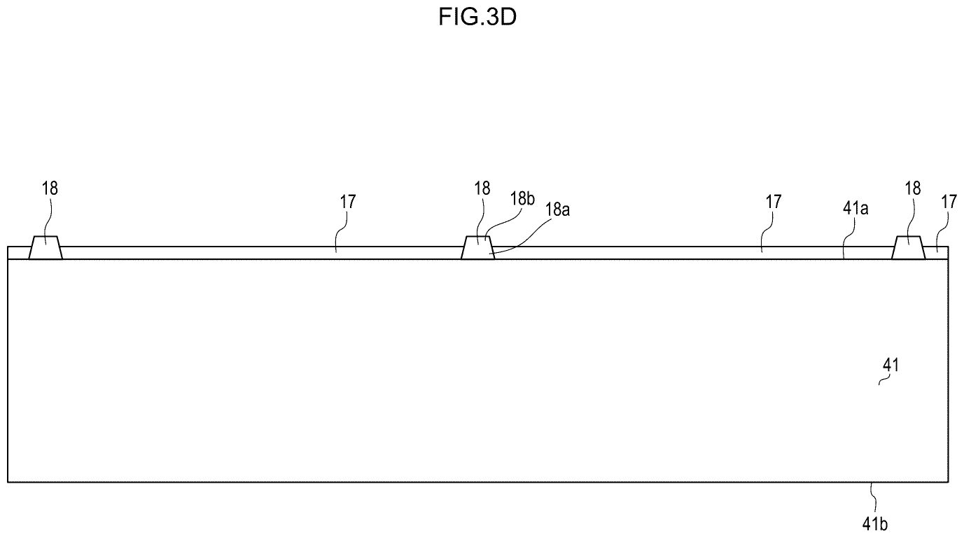

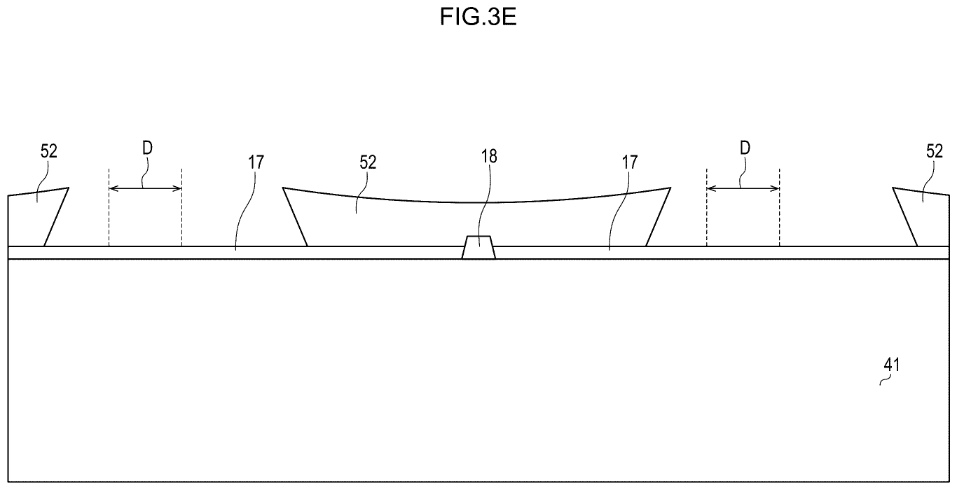

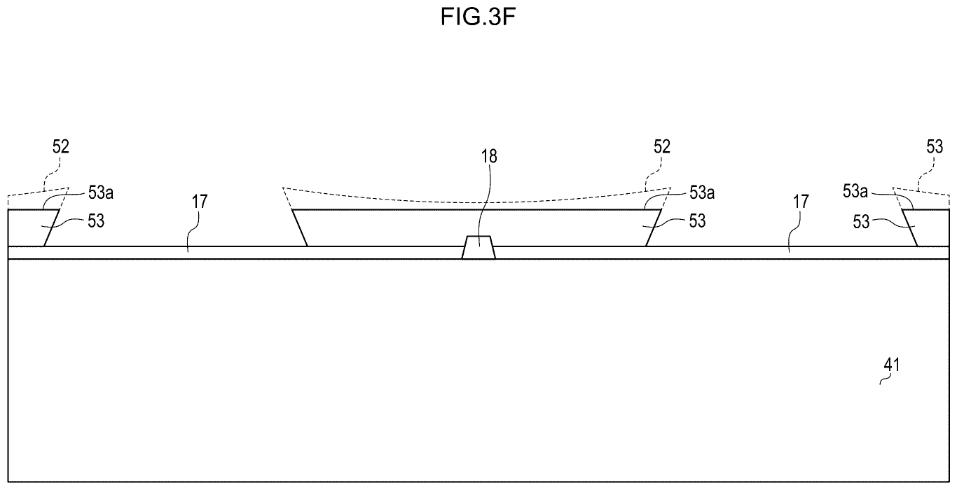

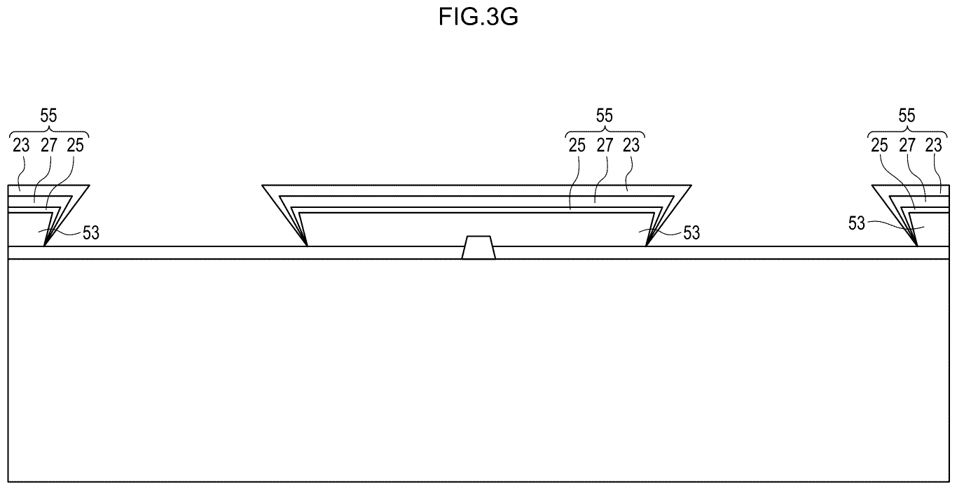

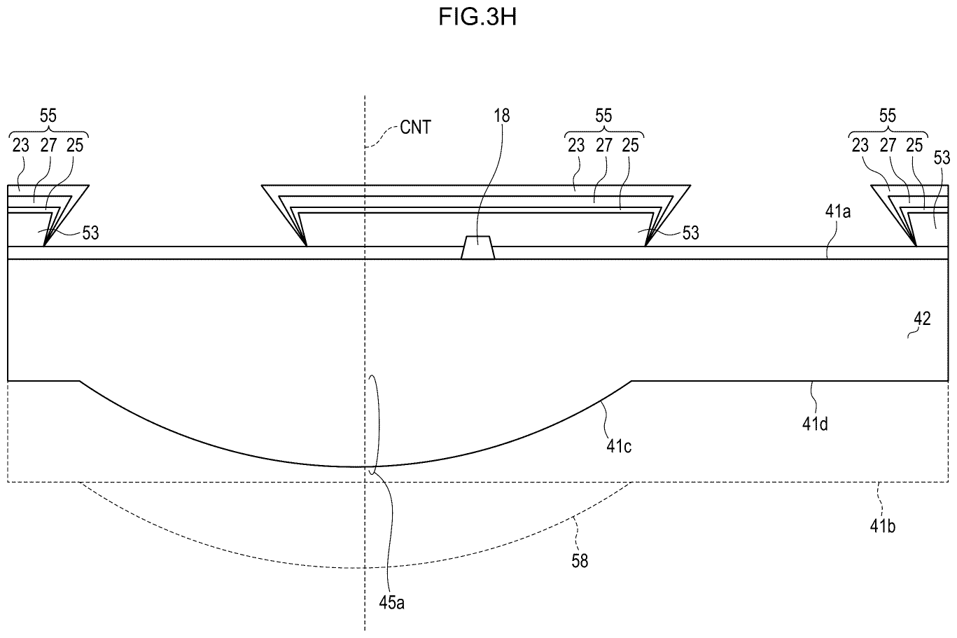

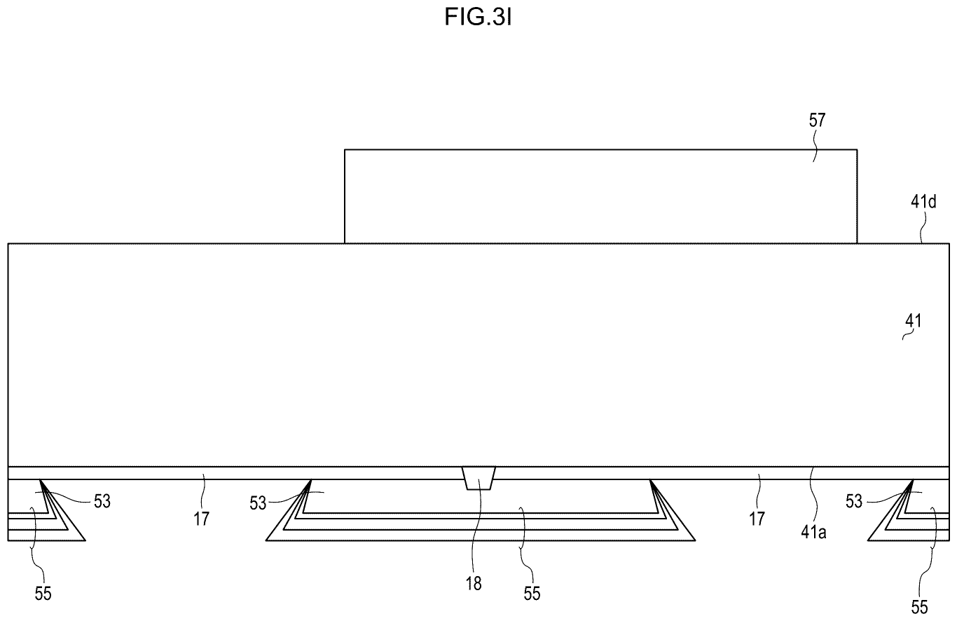

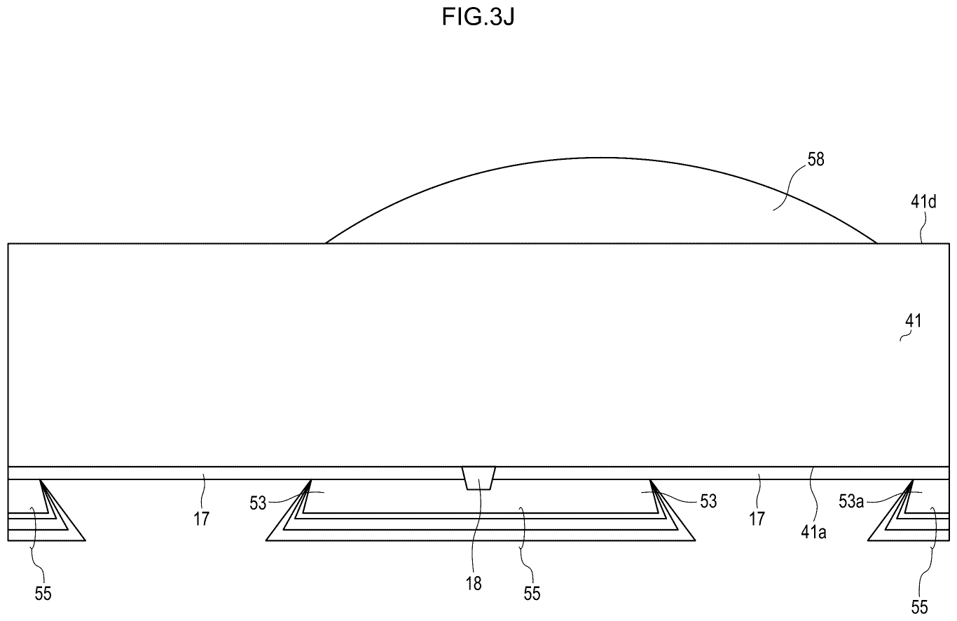

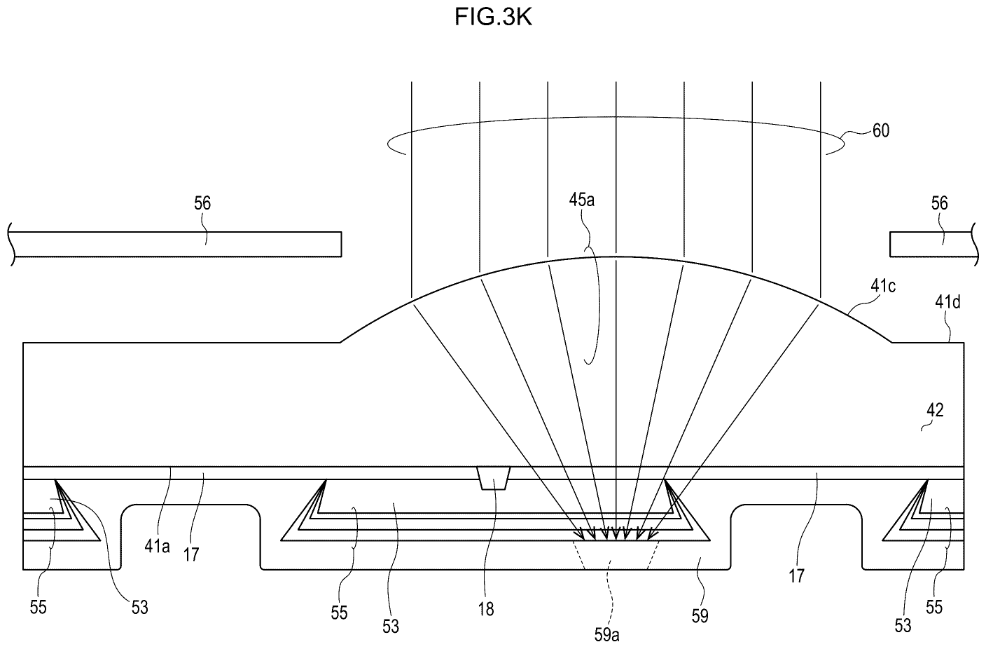

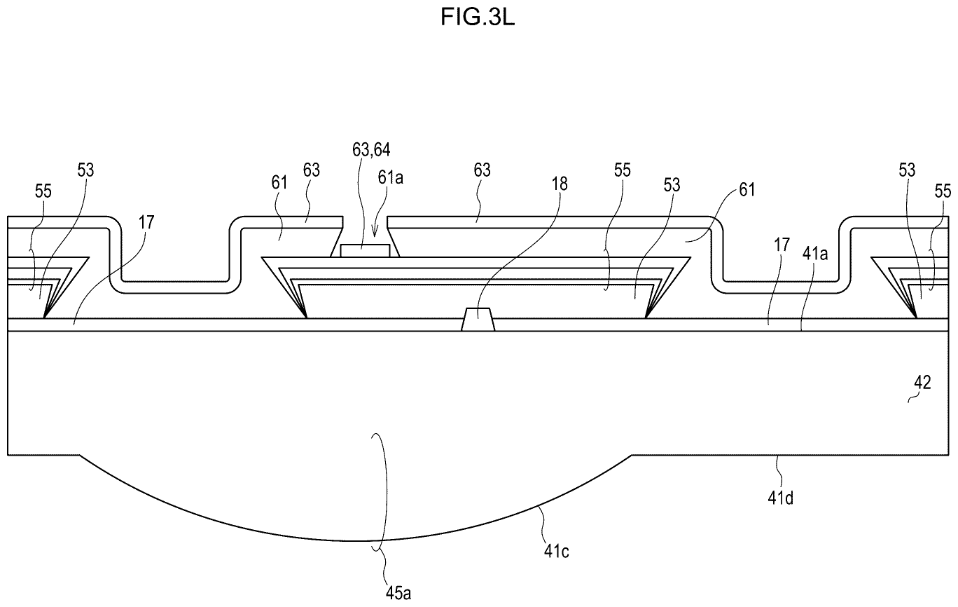

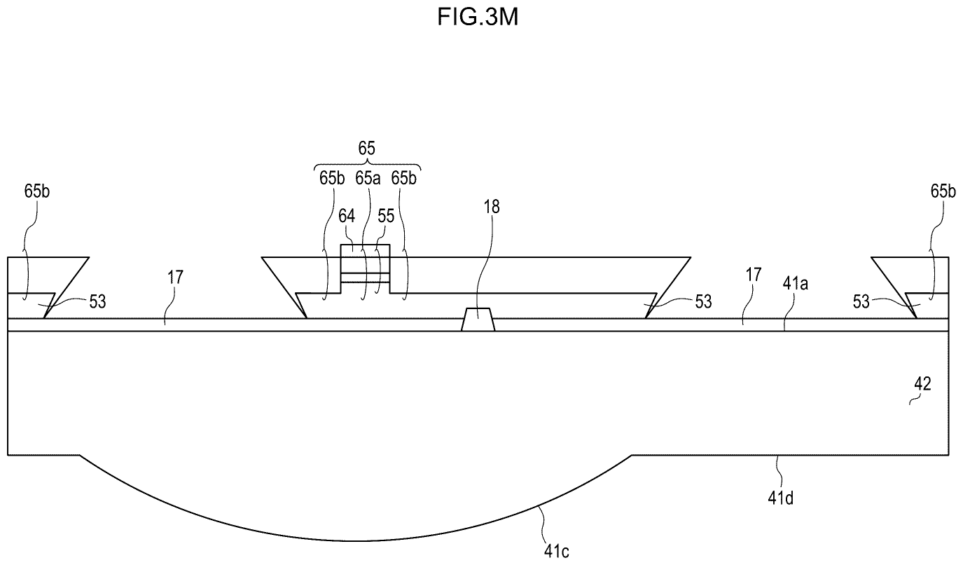

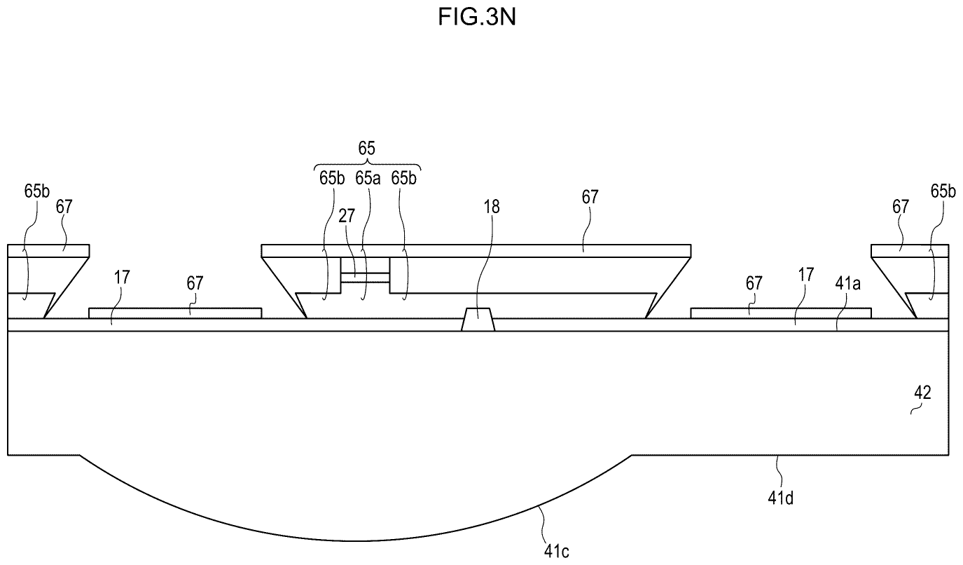

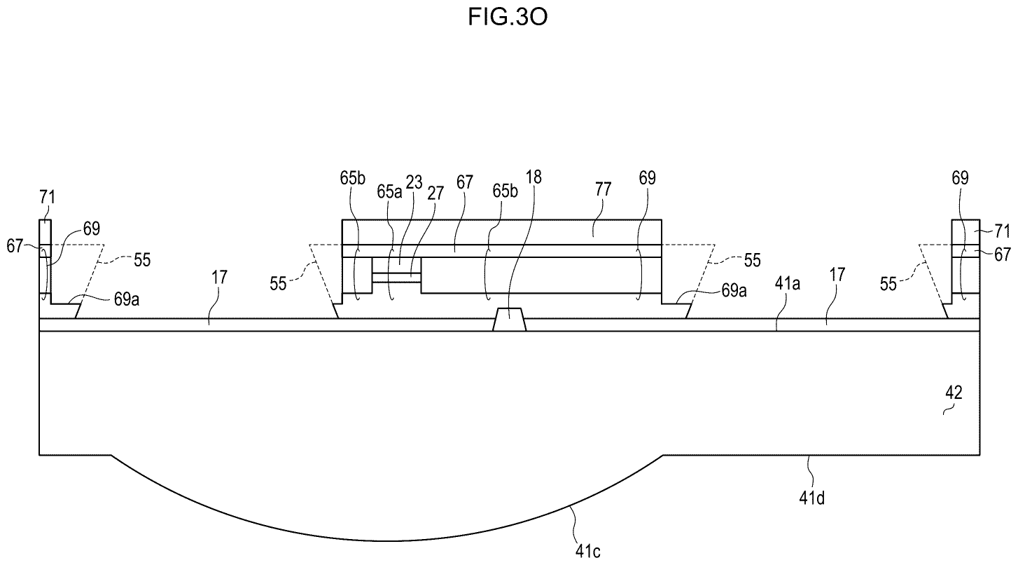

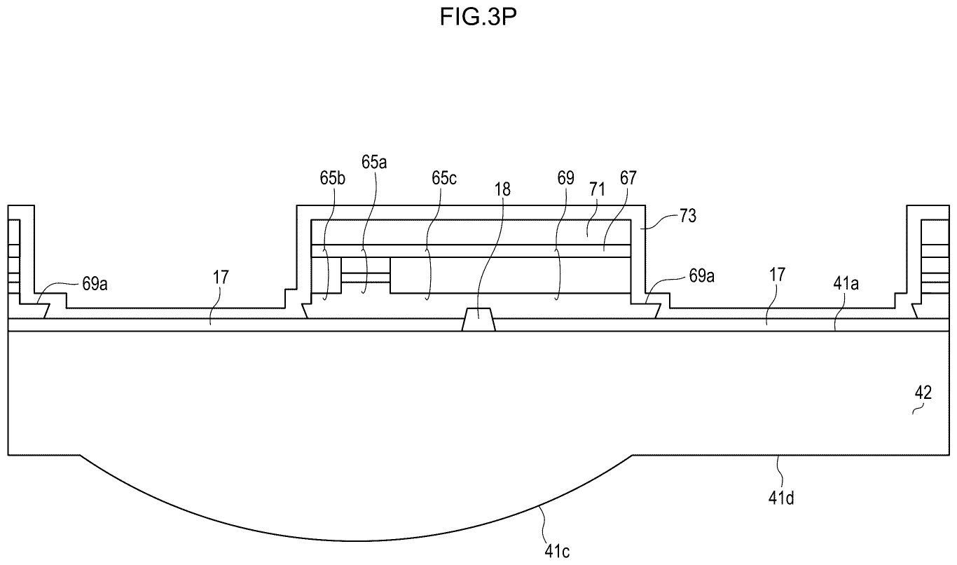

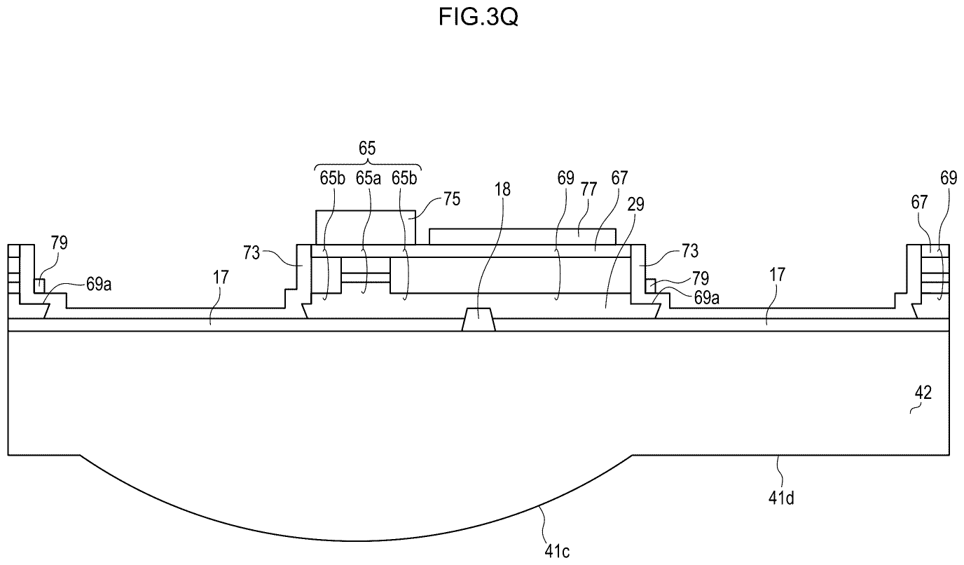

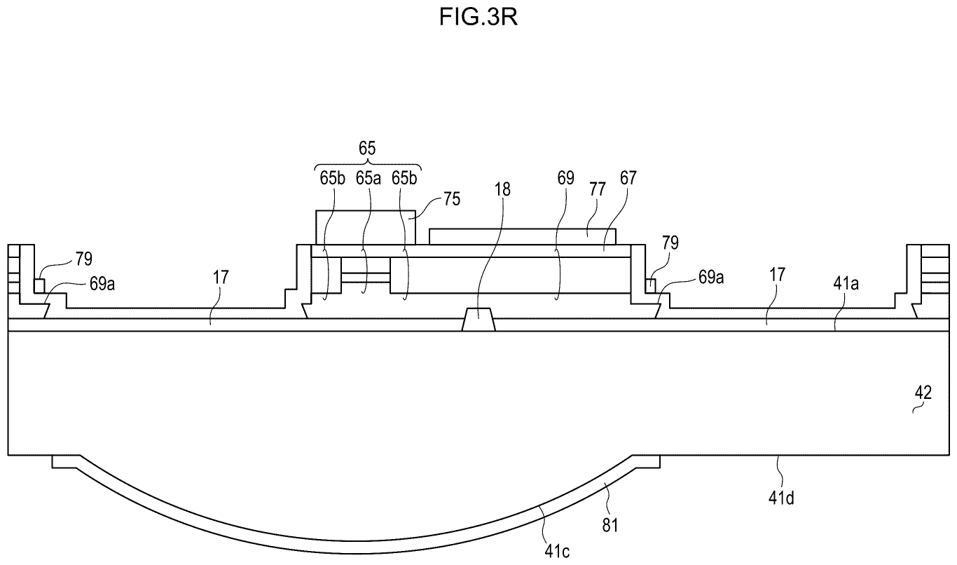

The VCSEL 11 further comprises a III nitride template plug 18, which extends from the first face 21a of the oxide substrate 21 to the semiconductor section 15 in a through hole 17a included in the dielectric filter layer 17. The through hole 17a extends in the first axial direction Ax1. The III nitride template plug 18 has an embedded portion 18a, which is also shown in FIG. 3D, and a projection 18b, which is also shown in FIG. 3D. The embedded portion is located in the through hole 17a and is disposed in contact with the first face 21a of the oxide substrate 21, and the projection protrudes into the semiconductor section 15.

As shown in FIG. 1, the curved surface 21c of the oxide substrate 21 has a center line CNT, and the III nitride template plug 18 and the center line CNT of the curved surface 21c are misaligned with each other.

The dielectric filter layer 17 has a reflective spectrum R3, which is configured to provide the optical window WIN, as shown in Portion (2) of FIG. 1. Referring to FIG. 1, the dielectric filter layer 17 includes, specifically, multiple dielectric layers 30, which are disposed on the oxide substrate 21, and the multiple dielectric layers 30 are arranged to configure a Fabry-Perot filter which can provide the reflective spectrum R3 with the optical window WIN. The first DBR mirror 13 has a reflective spectrum R1, as shown in Portion (1) of FIG. 1. The second DBR mirror 19 has a reflective spectrum R2, as shown in Portion (3) of FIG. 1. The reflective spectrums R1 and R2 each have a reflective wavelength bandwidth which includes the wavelength of λ0.

The magnitude relationship among the reflective spectrums R1, R2 and R3 is as follows: the reflectance value of each of the reflective spectrums R1 and R2 is much greater than that of the reflective spectrum R3; and the reflectance value of the reflective spectrum R2 may be greater than that of the reflective spectrum R1.

The III nitride active region 27 has a quantum well structure to generate light having a wavelength, which is located in the first reflection spectrum R1, the second reflection spectrum R2, and the optical window WIN of the dielectric filter layer 17. The lasing light can be emitted through, for example, the first DBR mirror 13 that has a reflectance lower than that of the second DBR mirror 19.

Specifically, the first DBR mirror 13 includes a first dielectric layer 13a and a second dielectric layer 13b, which are alternately arranged in the first axial direction Ax1 to act as, for example, a top mirror. The second DBR mirror 19 also includes a third dielectric layer 19a and a fourth dielectric layer 19b, which are also alternately arranged in the first axial direction Ax1 to act as, for example, a bottom mirror. The dielectric filter layer 17 extends between the semiconductor section 15 and the first face 21a of the oxide substrate 21.

In the VCSEL 11, the length of the extended optical cavity CAV may be more than 50 micrometers (>50 micrometers). The curved surface 21c has a radius of curvature which is more than 50 micrometers (>50 micrometers).

In the VCSEL 11, the first DBR mirror is planar and the second DBR mirror is curved, and a distance between the first DBR mirror 13 and the second DBR mirror 19 may be more than 50 micrometers. The semiconductor section 15 may have a thickness of more than 0.5 micrometers.

The VCSEL 11 further comprises a conductive layer 35 disposed on the semiconductor section 15. The conductive layer 35 may include either a III nitride semiconductor, such as n-type GaN, or a conductive inorganic material, such as indium tin oxide (ITO), or both. A part of the conductive layer 35 is disposed between the first DBR mirror 13 and the semiconductor section 15.

In the VCSEL 11, the semiconductor section 15 has an aperture structure 39 to confine electrical careers and lasing light. If needed, the semiconductor section 15 may further include a tunneling structure at the topmost layer of the semiconductor section 15 in addition to or in place of the aperture structure 39. The tunneling structure changes the type of conductivity, i.e., one of electron or hole to the other. The tunneling structure can be one of a tunnel junction or a buried tunnel junction. The tunnel junction can restrict the path of careers with the aperture structure 39, while the buried tunnel junction can restrict the path of careers without the aperture structure 39.

Referring to FIGS. 1 and 2, the semiconductor section 15 has a mesa structure 37. The mesa structure 37 includes a base region 37a and a mesa region 37b disposed on the base region 37a. The mesa region 37b is also provided with the p-type III nitride region 23, the III nitride active region 27 and a part of the n-type III nitride region of the III nitride region 25. The base region 37a includes the remainder of the n-type III nitride region of the III nitride region 25, and at the bottom of the mesa region 37b, the mesa region 37b may be surrounded by the n-type III nitride front face 25a at the top of the base region 37a.

The VCSEL 11 further comprises a first electrode 31, for example, an anode electrode, on the mesa region 37b, and a second electrode 33, for example a cathode electrode, outside the mesa region 37b. In an exemplary VCSEL 11, the anode electrode is disposed in contact with the ITO or the spreading semiconductor layer, and the cathode electrode is disposed in contact with the top face 25a of the n-type III nitride region 25 of the base region 37a. The first electrode 31 is disposed on the conductive layer 35 or the semiconductor section 15 outside the first DBR mirror 13, and may be in contact with the conductive layer 35 or the semiconductor section 15. The cathode electrode 33 may be disposed on the n-type III nitride front face 37c (25a) of the base region 37a outside the mesa region 37b.

In the VCSEL 11 that includes the conductive layer 31, the semiconductor section 15 has a first face 15a and a second face 15b at an opposite side from the first face 15a thereof. The dielectric filter layer 17 is disposed in contact with the first face 15a of the semiconductor section 15, and the conductive layer 31 is disposed in contact with the second face 15b thereof.

Referring to FIG. 1, which illustrates the outline of the VCSEL 11, the VCSEL 11 is provided with the two highly reflective DBR mirrors 13 and 19 with one of these mirrors being placed on a curved surface of the oxide substrate 21, and the oxide substrate 21 separates the two DBR mirrors 13 and 19 from each other to allow an extended optical cavity in a single step integration. In light of the fabrication of the VCSEL 11, the semiconductor section 15 is grown along the dielectric filter layer 17 by epitaxial lateral overgrowth (ELO) originating from the III-nitride template plug 18, and the dielectric filter layer 17 may have a Fabry-Perot multilayer film, which allows both a narrow optical bandpass in wavelengths and large optical rejection regions outside the narrow bandpass. The reflectivity of the dielectric filter layer 17 is engineered to be a very small at the lasing wavelength as compared to that of each of the DBR mirrors 13 and 19.

The greater separation of the DBR mirrors 13 and 19, which form the extended cavity, by the oxide substrate 21 allows the spacing of longitudinal modes of the extended cavity to be very small, and this very small spacing facilitates at least one of the longitudinal modes to be located within the narrow bandpass window WIN of the dielectric filter layer 17. In contrast, the shorter separation of the DBR mirrors 13 and the dielectric filter layer 17, which may form a parasitic cavity, by the semiconductor section 15 makes the spacing of longitudinal modes of the parasitic cavity large, and this large spacing facilitates most or all of the longitudinal modes of the parasitic cavity to be located outside the narrow bandpass window WIN. It is very likely that all of the longitudinal modes of the parasitic cavity are located outside the narrow bandpass window WIN. The narrower bandpass window of the dielectric filter layer 17 is combined with the wider reflecting wavelength ranges of the highly reflective DBR mirrors 13 and 19 to demonstrate the extended optical cavity. The active region, i.e., the gain medium, may be aligned with the DBR mirrors 13 and 19 such that the field maximum of the widely-separated longitudinal modes, which are to be rejected, misaligns with the location of the gain medium. Although the VCSEL 11 includes a number of cavities, at least one single longitudinal mode from the extended cavity in the narrow bandpass window WIN is selected, and light at the selected mode in the narrow bandpass window WIN can travel in the extended cavity between plano and curved mirrors to lase. Accordingly, the small mode spacing makes aligning the selected mode with the gain spectrum less complex, and the long cavity also makes aligning the selected mode with the gain medium less complex.

The VCSEL 11 concerns the placement of a curved mirror on the oxide substrate 21, and the dielectric filter layer 17, such as a Fabry-Perot filter, that is embedded between the plano and curved mirrors of the VCSEL 11. The curved mirror can return incoming electromagnetic radiation back to the gain medium at a reflection rate of nearly 90% by refocusing to provide the extended optical cavity of the VCSEL 11 with a lower diffraction loss. In addition, the oxide substrate 21 is made of transparent oxide (TO) material, which comprises ZnO, Ga₂O₃, or Al₂O₃, and the transparent oxide material and the curved mirror can make optical absorption therein negligibly small, allowing lossless optical transmission in the substantial part of the optical cavity of the VCSEL 11. The present device structure allows for the long cavity and better thermal performance in the VCSEL 11.

Referring to FIG. 1, the VCSEL 11 is provided with the curved DBR mirror, which is disposed on the backside of the substrate 21, as a bottom mirror. In light of the fabrication of the VCSEL 11, the curved DBR mirror is designed to be integrated in simple fabrication steps, e.g., forming a patterned dielectric laminate, i.e., the DBR mirror 19, along the curved backside of the substrate 21. The VCSEL 11 is also provided with a planar DBR mirror, which is located on the front side of the substrate 21 as a top mirror. In light of the fabrication of the VCSEL 11, the planar DBR mirror is designed to be integrated in simple fabrication steps, e.g., forming a patterned dielectric laminate, i.e., the DBR mirror 13, along the planar face of the semiconductor section 15 as a top-mirror. The planar DBR mirror 13 and the curved DBR mirror 19 form the extended cavity with the dielectric filter layer 17 embedded in between. The dielectric filter layer 17 preferably includes an antireflective coating or a Fabry-Perot structure, which comprises dielectric materials, to exhibit narrow bandpass characteristics around a desired wavelength and to reflect the light of optical wavelengths outside the bandpass wavelengths. In light of the fabrication of the VCSEL 11, the semiconductor section 15, which is formed by epitaxial lateral overgrowth (ELO), originates from the template plug 18, which may fabricated on the oxide substrate 21 by deposition and etching. The semiconductor section 15 includes a light generating structure which is provided with the p-type III nitride region 23, the n-type III nitride region 25 of the III nitride region 29, and the III nitride active region 27 between the p-type III-nitride region 23 and the n-type III nitride region 25.

The filter layer 17 preferably can be a Fabry-Perot structure made of all dielectrics. In light of the fabrication of the VCSEL 11, the dielectric filter layer 17 can work as an ELO mask, which allows the epitaxial laterally overgrowth of III nitride from the III nitride template plug 18, to prevent III nitride from depositing thereon, and works as a supporting structure for the III nitride thus grown by ELO on the oxide substrate 21. The ELO deposition of III nitride for the semiconductor section 15 embeds a part of the dielectric filter layer 17. Accordingly, laminating the filter layer 17, which has an ELO mask structure, is designed to offer a simple step integration of the thin semiconductor section 15 on the TO substrate 21 without the substrate removal and bonding. This filter layer 17 has optical characteristics that offer both the narrow bandpass, which allows lasing at a mode of the major optical cavity, and the rejection bands, which can prevent one or more modes of the parasitic optical cavity from lasing.

The VCSEL 11 is provided with the first DBR mirror 13 on the semiconductor section 15, which extends over the filter layer 17. The first DBR mirror 13 is provided with first dielectric layers 13a and second dielectric layers 13b alternatively arranged in the first axial direction Ax1, and the material of the first layers 13a is different from the second layers 13b.

The VCSEL 11 is provided with the second DBR mirror 19 separated from the first DBR mirror 13 by the semiconductor section 15 and the oxide substrate 21. The second DBR mirror 19 includes third dielectric layers 19a and fourth dielectric layers 19b alternatively arranged in the first axial direction Ax1, and the material of the third layers 19a is different from the fourth layers 19b.

The VCSEL 11 further includes an omnidirectional reflector layer 40. The omnidirectional reflector layer 40 covers the semiconductor section 15 and the dielectric filter layer 17 to reflect stray light of the lasing wavelength outwards, thereby preventing the stray light from interfering with the lasing in the cavity. The omnidirectional reflector layer 40 also works as a passivation layer between the cathode electrode 33 and anode electrode 31.

The cavity CAV has a total cavity length which can be defined as a distance between the curved surface 21c and the substantially planar surface that is disposed in contact with the first DBR mirror 19. In an exemplary structure of the VCSEL 11, the distance between the curved surface 21c and the planar top face 21a of the TO substrate 21 can be 50 to 1000 micrometers, which is used as the extended cavity, and the thickness of the semiconductor section 15 is roughly to 0.5 to 4 micrometers, which is also used as the extended cavity.

The semiconductor section 15 is provided with the aperture structure 39. The aperture structure 39 has a conductive aperture portion 39a and a less conductive portion 39b which surrounds the aperture conductive portion 39a. The aperture conductive portion 39a provides the VCSEL 11 with the electrical path that is formed between the anode electrode 31 and the cathode electrode 33. Carriers, such as electron and hole, flow through the electrical path, and are recombined in the III nitride active region 27 to generate light, which emits from one of the DBR mirrors, for example, the first DBR mirror 13. The conductive aperture portion 39a is located laterally away from the template plug 18 to reduce optical interference which may be caused by the template plug 18. Preferably, the conductive aperture portion 39a may be separated apart from the sidewall of the template plug 18 by at least about 3 micrometers, which is measured along the dielectric filter layer 17. The extended cavity, the major portion of which is constituted by the oxide substrate 21, should be dimensionally designed such that the template plug 18 runs outside the substantial portion of the circular cone associated with the curved DBR mirror 19.

Referring to FIG. 2, the III nitride template plug 18, the curve surface 21c, and aperture structure 39 are depicted by dashed line. The second axial direction Ax2 and the third axial direction Ax3 are shown in addition to the first axial direction Ax1, and the three axial directions are perpendicular to each other. For example, the conductive aperture portion 39a is located asymmetrically with respect to the liner template plug 18, and the asymmetric design facilitates both the arrangement of the anode and cathode electrodes on the front side and the location of the curved DBR mirror 19 on the back side. The semiconductor section 15 is formed by being laterally grown on the dielectric filter layer from an exposed sidewall face and top face of the III nitride template plug 18 outwards. This formation allows the III nitride template plug 18 to connect the semiconductor section 15 with the TO substrate 21, and the template plug 18 forms a thermal path of III nitride which allows thermal dissipation from the active region 27 to the oxide substrate 21. This structure, which provides the VCSEL 11 with the thermal path, ensures that the thermal energy is sunk through the template plug 18 by the better thermal conductive TO substrate 21.

A description will be given of an exemplary method for fabricating a VCSEL according to the present embodiment with reference to FIGS. 3A to 3R. FIGS. 3A to 3R each are a cross-sectional view, which shows a process step in the fabrication method, and the cross-section is taken along the line that corresponds to I-I line shown in FIG. 2. In order to avoid duplicated description in the following, the reference numerals that are have been used in FIGS. 1 and 2 are used below, where possible. In the subsequent description, III nitride can be deposited by, for example, metal organic chemical vapor deposition (MOCVD) or molecular beam epitaxy (MBE).

Referring to FIG. 3A, an oxide wafer 41, which corresponds to the oxide substrate 21 of the VCSEL 11, is prepared which includes transparent material, such as ZnO, Ga₂O₃, Al₂O₃, and then a III nitride film 43, such as gallium nitride (GaN), is deposited on the top face of the oxide wafer 41.

Referring to FIG. 3B, a resist mask 45 is formed on the III nitride film 43, and the III nitride film 43 is etched with the mask 45 to form one or more III nitride template plugs 18, each of which has a width “W” and height “H”. The III nitride template plugs 18 each include a single crystalline III nitride with a very low defect density. For example, the III nitride template plugs 18 may run linearly along the top face of the oxide wafer 41 and may be arranged in parallel at a pitch of “P”.

Referring to FIG. 3C, a dielectric multilayer film 47 is deposited on the oxide wafer 41 and over the III nitride template plugs 18. The dielectric multilayer film 47 has a thickness smaller than the height of the III nitride template plugs 18 and the thickness of the III nitride film 43, and may have a structure which can form a Fabry-Perot filter.

The dielectric multilayer film 47 for an exemplary dielectric Fabry-Perot structure has the following exemplary layer structure: “(HL)m2nH(LH)m”, where “H” and “L” stand for respective layers with high and low refractive indices, with these respective layers having a quarter wave optical thickness, and “m” and “n” are integers. Specifically, the representation, “(HL)m”, indicates m-times alternations of a high refractive index layer and a low refractive index layer; the representation, “2nH”, indicates 2n-times thickness of a high refractive index layer; and the representation, “(LH)m”, indicates m-times alternations of a low refractive index layer and a high refractive index layer. Designing the Fabry-Perot spectrum (R3) in terms of the refractive indices and the layer thicknesses of dielectric material enables both a high transmission optical window at a central wavelength λ0 and high reflection spectral regions on both sides of the high transmission optical window.

Referring to FIG. 3D, the dielectric filter layer 17 is produced from the dielectric multilayer 47 by processing the dielectric multilayer film 47 by etching, and in the etching process, a mask (not shown in the figure) may be used which is formed on the dielectric multilayer 47 and has respective openings at the III nitride template plugs 18. Each of the III nitride template plugs 18 is located at a corresponding opening of the dielectric filter layer 17 thus formed, and has a lower portion and an upper portion. The lower portion 18a of the III nitride template plug 18 is embedded in the opening of the dielectric filter layer 17, and the upper portion 18b of the III nitride template plug 18 protrudes from the top face of the dielectric filter layer 17.

In the process in which an intermediate product shown in FIG. 3D is obtained, a starting base 51 has been prepared which is provided with an oxide base as the oxide wafer 41, the arrangement of the III nitride template plugs 18, and the dielectric filter layer 17. The oxide wafer 41 has a first face 41a and a second face 41b at an opposite side from the first face 41a. The dielectric filter layer 17 and the III nitride template plugs 18 are arranged in the first face 41a. The reflective spectrum (R3) of the dielectric filter layer 17, which extends along the first face 41a, is configured to provide the optical window (WIN). Light travels in the extended optical cavity between the flat and curved DBR mirrors 13 and 19 to pass through the dielectric Fabry-Perot filter twice for every optical round trip. The dielectric filter layer 17 is provided with a Fabry-Perot filter structure which offers both a narrow bandpass and rejection bands on the both sides of the narrow bandpass. If needed, the dielectric multilayer film 47 may be deposited and then patterned to form strip openings, which are periodically arranged, on the first face 41a of the oxide wafer 41, and III nitride may be selectively grown at the strip openings to form the III nitride template plugs 18.

Referring to FIG. 3E, after forming the starting base 51 that includes the arrangement of the dielectric filter layer 17 and the III nitride template plugs 18, a III nitride regions 52 are epitaxially grown along the dielectric filter layer 17 from the III nitride template plugs 18 on the starting base 51. The III nitride regions 52 are grown by ELO from the sides and tops of the III nitride template plugs 18 to form wing-like III nitride islands, and the adjacent III nitride regions 52 are isolated from each other. The III nitride islands are formed by the deposition of III nitride material by ELO from the template plugs 18, and define dicing streets “D” which run between the adjacent III nitride islands. The dicing streets “D” also define individual VCSEL sections, which corresponds to VCSEL chips. The III nitride regions 52 may be partially or entirely doped with n-type dopant, and extend outward from the template plugs 18.

Referring to FIG. 3F, if needed, prior to growing the subsequent semiconductor laminate, the III nitride region 52 is planarized by at least one of polishing or etching to form a III nitride region 53 with a planar top face 53a.

Referring to FIG. 3G, after growing the III nitride region 53, a semiconductor laminate 55 is epitaxially formed which includes III nitride device layers. The III nitride device layers are provided with the n-type III nitride region 25, the III nitride active region 27, and the p-type III nitride region 23. Specifically, the n-type III nitride region 25, the III nitride active region 27, and the p-type III nitride region 23 are sequentially grown on the planar face of the III nitride region 53.

Specifically, the nitride region 25 can include GaN-or AIN-based material doped with n-type dopant, which allows the supply of electrons to the III nitride active region 27, and the p-type III nitride region 23 can include GaN- or AlN-based material doped with p-type dopant, which allows the supply of holes to the III nitride active region 27. The III nitride active region 27 can include GaN- or AlN-based material, such as GaN, InGaN, AlN, AlGaN or AlInGaN. The III nitride active region 27 may be provided with a single well layer or a quantum well structure, such as a single quantum well (SQW) or multiple quantum wells (MQWs). If needed, the buried tunnel junction or tunnel junction layers may be grown after depositing the p-type III nitride region 23.

Referring to FIG. 3H, after growing the semiconductor laminate 55, the oxide wafer 41 is processed at the second face 41b to form a curved surface 41c and a newly-produced back face 41d which are produced from the second face 41b, and if needed, the second face 41b may be a polished face. Specifically, the curved surface 41c of the oxide wafer 41 serves as a micro lens 45a. The curved surface 41c of the oxide wafer 41 has a center axis CNT, and as shown in FIG. 3H, the III nitride template plug 18 and the center axis CNT of the curved surface 41c are not aligned with each other. The oxide wafer 41, such as a sapphire wafer, is processed at the polished surface thereof to fabricate the curved surface 41c, such as a micro lens 45a, and the back face 41d. The curved surface 41c can be positioned at a predefined location which is aligned such that the focus of the micro lens 45a helps to determine the location of an aperture structure which confines careers. The aperture structure will be described later.

Referring to FIGS. 3H to 3J, the curved surface 41c, which works as a micro lens, can be fabricated using a thermal reflow technique referred in Ref. [NPL 11]. Specifically, as shown in FIG. 3I, a resist film can be formed on the back side of the oxide wafer 41 and processed by standard photolithography to form a patterned resist 57, such as a photoresist micro disk 45a. Then, as shown in FIG. 3J, the patterned resist 57 is subjected to thermal treatment at an elevated temperature, for example, with a hot plate, and the high temperature thermal treatment deforms the patterned resist 57 into a lenticular shape, which can be used as a sacrificial photoresist mask 58. Further, as shown in FIG. 3H, the lenticular-shaped resist 58 and the back side 41b of the oxide wafer 41 can be processed by reactive ion etching (RIE), so that the shape of the lenticular-shaped resist 58 is transferred into the oxide wafer 41. Specifically, the oxide wafer 41 is thinned, and the curved surface 41c, such as a micro lens 45a, is left at the back side 41d of the thinned oxide wafer, which will be referred to as the oxide substrate 42. Thinning the oxide wafer 41 can adjust the length of the extended optical cavity. Accordingly this process allows not only the formation of the curved surface 41c but also the adjustment of the cavity length.

Referring to FIG. 3K, a photoresist film 59 is formed on the front face of the oxide substrate 42 to cover the semiconductor laminate 55 and the dielectric filter layer 17. Then, the curved surface 41c at the back face 41d of the oxide substrate 42 is illuminated with a photo mask 56 through which exposure light 60 passes, and the exposure light 60 passes through the curved surface 41c to focus at a point, for example, in the portion of the photoresist film 59 that covers the top face of the semiconductor laminate 55, whereby the exposed portion 59a of the photoresist film 59 is formed.

Referring to FIG. 3L, the development of the exposed photoresist film 59 forms a resist mask 61 with a pattered opening 61a. Then, a film 63 is deposited both on the resist mask 61 and in the pattered opening 61a, and the removal of the resist mask 61 leaves a mask 64 which is produced from the film 63. The film 63 may be made of a Ti/Au or dielectric layer.

Referring to FIG. 3M, the fabrication of the VCSEL 11 that includes no buried tunnel junction needs to form an aperture structure 65. Specifically, the mask 64 is used to perform ion implantation to form the aperture structure 65. The aperture structure 65 thus formed includes an aperture region 65a and an isolation region 65b surrounding the aperture region 65a. The implantation of ion, such as hydrogen atom, n-type dopant atom, and/or p-type dopant atom, into the semiconductor laminate 51 with the mask 64 produces the aperture structure 65 in the semiconductor laminate 55. The aperture structure 65 is provided with the semiconductor aperture region 65a, which can form an electrical path through which careers flow, and the isolation region 65b, which can confine light and careers into the semiconductor aperture region 65a. After the ion implantation, the mask 64 is removed.

Alternatively, the fabrication of the VCSEL 11 in which the semiconductor laminate 55 includes a buried tunnel junction needs to pattern tunneling layers, such as p⁺⁺ GaN and n⁺⁺ GaN layers, which the semiconductor laminate 55 may include. Specifically, the tunneling layers can be etched with the mask 64 to form a buried tunnel junction. After the etching, the mask 64 is removed, and then the regrowth of III nitride is performed to deposit a doped semiconductor layer, acting as a current spreader, which covers the buried tunnel junction.

Referring to FIG. 3N, after removing the mask 64 in the fabrication of the VCSEL 11 that includes no buried tunnel junction, a conductive layer 67 is deposited on the semiconductor laminate 55 so as to cover both the semiconductor aperture region 65a and the isolation region 65b. The conductive layer 67 may include a heavily-doped III nitride semiconductor layer, such as GaN or AlGaN, and/or an inorganic layer, such indium tin oxide (ITO), and is transparent to light from the III nitride active region 27. For example, the conductive layer 67 can be deposited on the oxide substrate 42 with no mask.

Referring to FIG. 3O, a mesa structure 69 is produced from the semiconductor laminate 55. Specifically, a photoresist is formed on the oxide substrate 42a to cover the semiconductor laminate 55, and then patterned to form a resist mask 71. The resist mask 71 is used to expose the underlying n-type GaN region of the semiconductor laminate 55 by etching, thereby forming the mesa structure 69, which includes the III nitride active region 27 and the p-type III nitride region 23. Outside the mesa structure 69, an etched face 69a of the n-type III nitride region is produced from the semiconductor laminate 55.

Referring to FIGS. 3P and 3Q, after forming the mesa structure 69 with the resist mask 71 left on the oxide substrate 42, an omnidirectional reflector (ODR) layer 73 is formed by depositing an omnidirectional reflective film 73 over the oxide substrate 42 and the resist mask 71 and then removing the resist mask 71, i.e., by lift off. As shown in FIG. 3P, the ODR layer 73 thus formed covers the side face of the mesa structure 69 and the top of the dielectric filter layer 17, and has an opening at the top of the mesa structure 69. The ODR layer 71 functions as a reflector of stray light of the lasing wavelength of the VCSEL 11, and also functions as a passivation layer between anode and cathode electrodes which will be formed in later process steps.

Referring to FIG. 3Q again, after forming the ODR layer 73, a first distributed Bragg reflector (DBR) laminate 75 and a first electrode 77 are formed by lift off on the conductive layer 67, and a second electrode 79 is formed by lift off on the etched face 69a of the n-type III nitride region 25 outside the mesa structure 69.

Specifically, the first DBR laminate 75 may be formed by lift off, and is aligned with the aperture structure 65 or the buried tunnel junction. The first electrode 77, such as an anode electrode, may be located outside the first DBR laminate 75, and is disposed in contact with the conductive layer 67 or the regrown semiconductor layer. The second electrode 79, such as a cathode electrode, may be located outside the mesa structure 69 after patterning the ODR layer 73 to form an opening of the ODR layer 73. This opening of the ODR layer 73 allows the second electrode 79 to be disposed in contact with the etched n-type III nitride face 69a of the III nitride region 25.

Referring to FIG. 3R, a second DBR mirror laminate 81 is formed on the curved surface 41c of the oxide substrate 42. If needed, the second DBR mirror laminate 81 is pattered to expose a part of the back surface 41d of the oxide substrate 42, and then bonding material, such as solder ball, may be formed on the exposed back surface 41d of the oxide substrate 42.

These processes complete a VCSEL, for example, the VCSEL 11. This structure allows the VCSEL 11 thus fabricated to be bonded to a sub-mount on the curved DBR side using solder bumps.

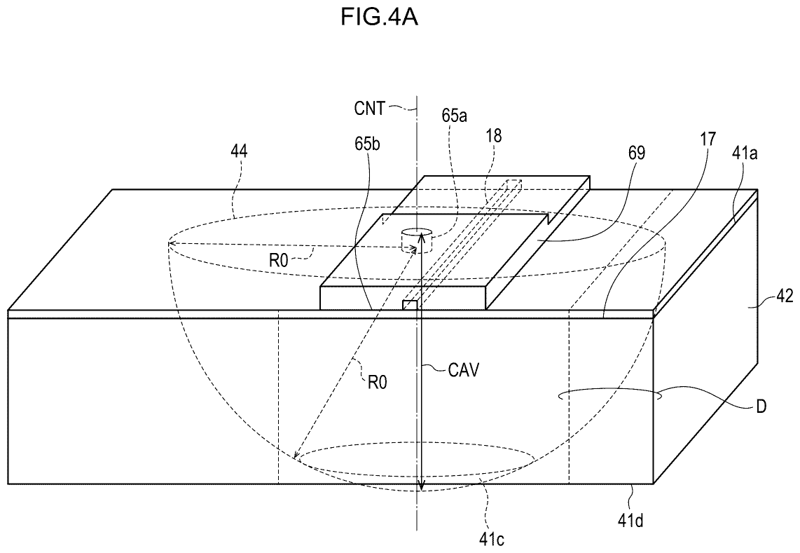

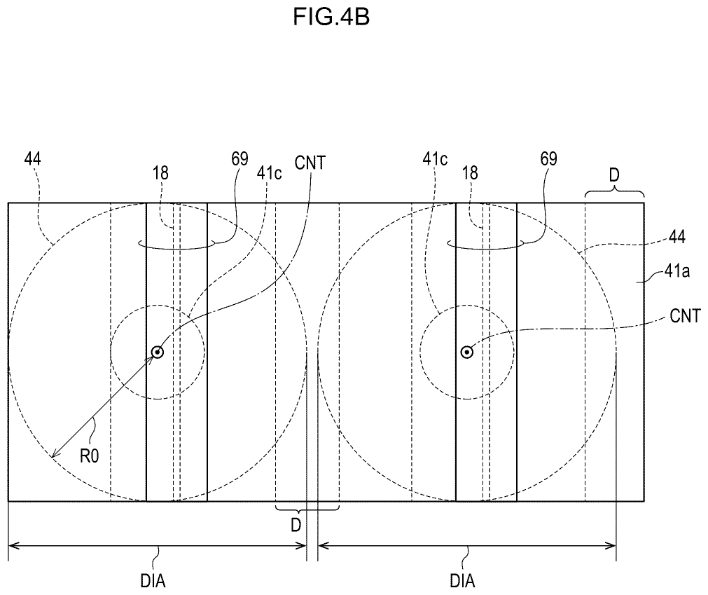

FIG. 4A is a diagrammatic perspective view showing one chip section including the template plug 18, the curved surface 41c as a lens structure, and the aperture structure 65 in the mesa structure 69. FIG. 4B is a plan view showing two chip sections on the oxide substrate 42 to which the above fabrication processes have been applied.

In the above fabrication method, the oxide substrate thus fabricated is separated into VCSEL chips by a separating process, such as dicing and/or etching. Please note that the present oxide substrate is provided with the arrangement of the mesa structures and dicing streets which run between the adjacent mesa structures. The dicing streets of the present product thus fabricated include no semiconductor structures. The omnidirectional filter layer covers the top face of the oxide substrate except for the top of the mesa structure, and if needed, may be removed at the dicing streets by photo lithography and etching. Since the second DBR laminate can be patterned to be located on and around the curved surface 41c, no material covers the dicing streets at the backside face of the oxide substrate.

In the VCSEL 11 thus fabricated, the length of the extended optical cavity CAV may be more than 50 micrometers (>50 micrometers). The curved surface 41c has a radius of curvature which is more than 50 micrometers (>50 micrometers).

In the VCSEL 11, the first DBR mirror 13 is planar and the second DBR mirror 19 is curved, and a distance between the first DBR mirror 13 and the second DBR mirror 19 is more than 50 micrometers. The semiconductor section 15 has a thickness of more than 0.5 micrometers.

In FIGS. 4A and 4B, a hemisphere circle 44 is depicted to show a virtual sphere which extends along the curved surface 41c. For example, when a radius of curvature R0 for the curved mirror 21c is about 100 micrometers, the hemisphere circle 44 has a diameter “DIA” of 200 micrometers on the top face 21a.

The spacing of the adjacent template plugs 18 is associated with a fill rate which indicates the ratio of the total area of the device sections on a single wafer to the top area of the wafer. The dicing streets define the arrangement of chip areas, each of which is prepared for a single VCSEL device. The template plugs 18 may be arranged in one direction periodically, or may be long micro strips across the whole wafer, or may be terminated micro strips lengthwise within a single chip dimension, or may be terminated strips which are arranged in a checkerboard pattern and if needed, is partially interleaved at their ends to obtain one benefit of growth, i.e., lowering edge effects.

The arrangement of the template plugs 18 is associated with the location of the dicing streets. Semiconductor sections grown from the template plugs cannot be made large because of the ELO, and the ELO of the semiconductor sections is terminated before they reach the adjacent ones.

Preferably, the semiconductor sections should be provided with a size which is wider than that of the designed aperture portion of the aperture structure and smaller than that of the period of the arrangement of the template plugs 18.

Preferably, the dicing streets should exclude III nitride material which is to be sliced. The slicing of the oxide substrate can be performed at the dicing streets by dicing blade, laser scribing and/or plasma etching. One benefit of no III nitride material within the dicing streets is to save semiconductor layers from being wasted.

The conducting aperture portion of the aperture structure may be placed near the edge of the wing-like semiconductor island, which is grown outward from one template plug by ELO. The benefits of this device are to accommodate electrical pads on the chip surface and to reduce crystalline defects or irregularities that may be contained in an immediate region next to template plug. Another benefit thereof is to separate the aperture structure away from the reference plane that extends perpendicular to the top face of the oxide substrate at the center of the template plug, thereby eliminating optical loss.

The narrower dicing street allows the more device sections to be arranged on the single wafer.

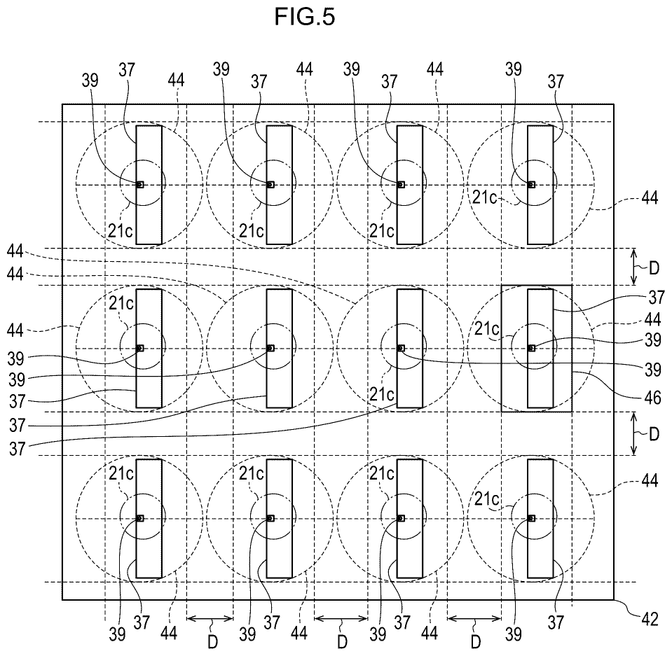

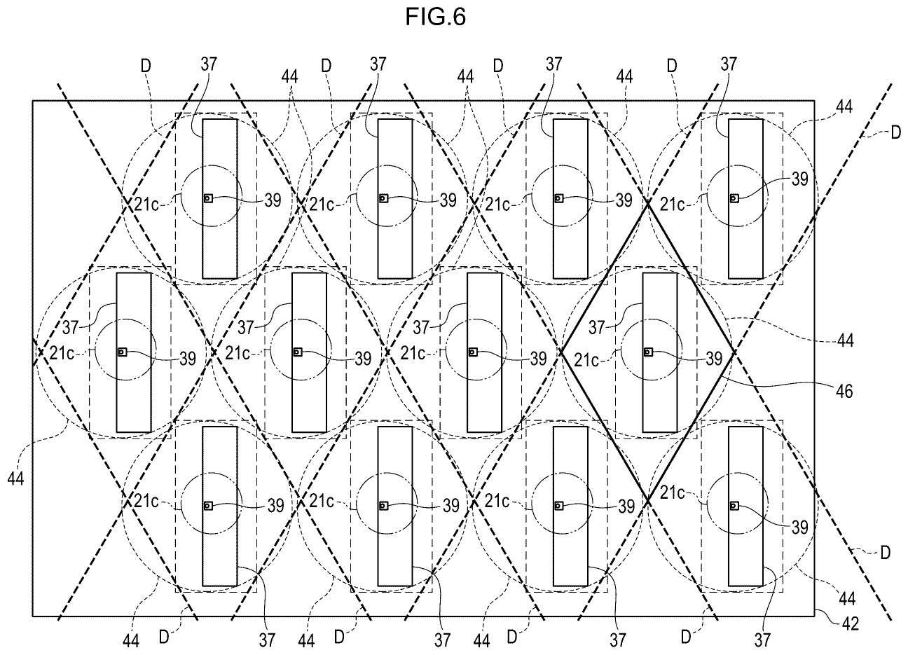

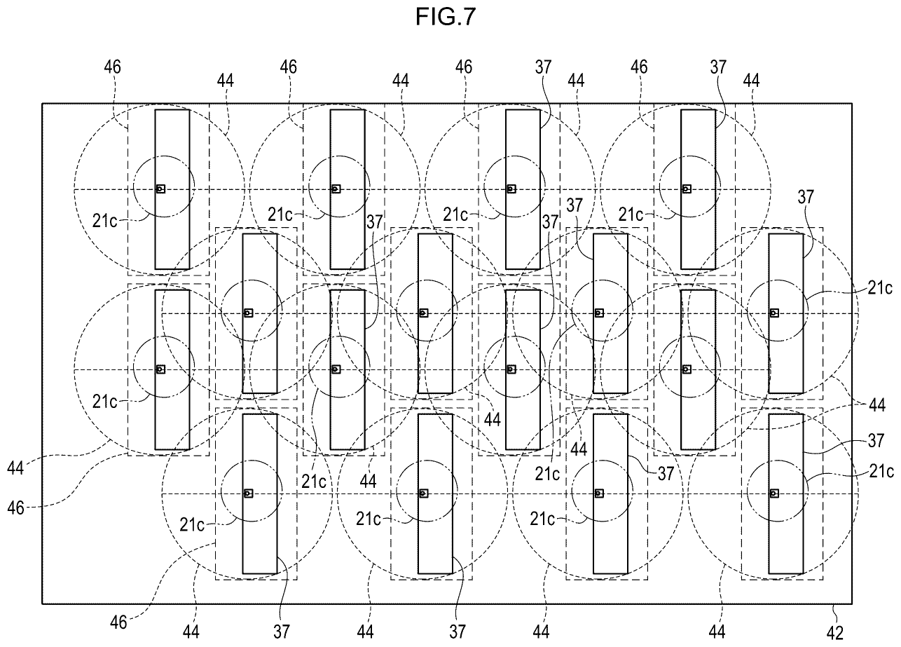

FIGS. 5 to 7 are schematic views each showing an exemplary arrangement of the device sections on the TO substrate. Referring to FIGS. 5 to 7, the typical arrangements of the device sections on the TO substrate are shown. The device sections are arranged to form a two-dimensional array, and the dicing streets D run to define the array. In FIGS. 5 and 6, the hemisphere circles 44 are separated from each other. In FIG. 7, the hemisphere circles 44 are partially overlapped, while the curved surfaces 21 are separated from each other. The boundary of the device sections 46 are depicted by dashed line.

A person having skill in the art could understand various modifications from the above arrangements, for example, a populated version or a less populated version of the arrangement of the VCSEL device sections.

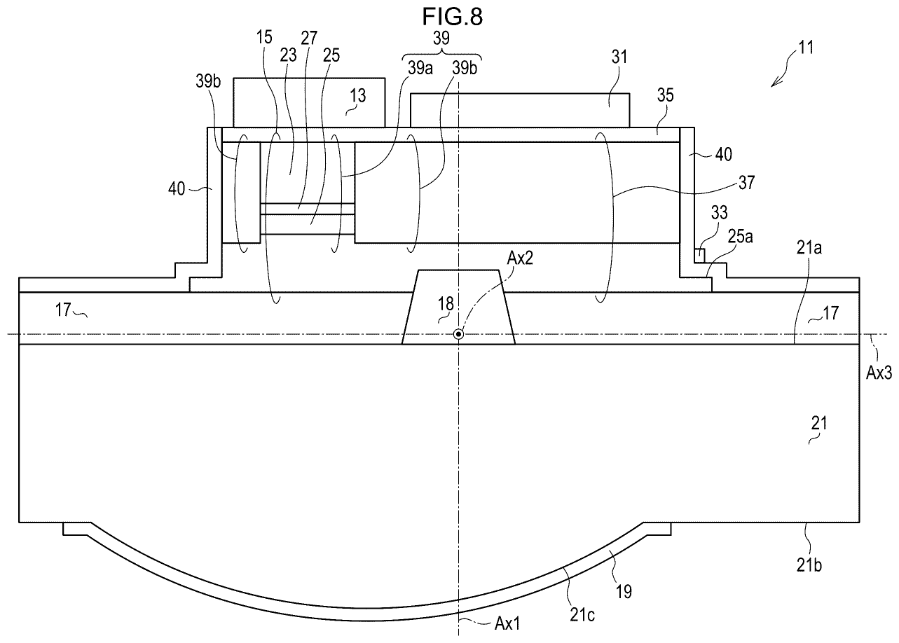

FIG. 8 is a schematic view showing a VCSEL according to one embodiment of the present disclosure. The VCSEL 11 is provided with the conductive layer 35 and the aperture structure 39 that confines careers and lasing light. The conductive layer 35 forms an electrical route from the first electrode 31, which is located next to the first DBR mirror 13, to the conductive aperture portion 39a, which is located just below the first DBR mirror 13 to align with the cavity, of the aperture structure 39.

A description will be given of an exemplary process flow in a method for fabricating the VCSEL 11, which includes the conductive layer working as a current spreading layer.

The method includes the following steps.
1. Preparing a starting base, where preparing the starting base includes forming a template plug of GaN, which runs straight on the TO wafer in the second axial direction Ax2 perpendicular to the first axial direction Ax1; and forming a dielectric Fabry-Perot filter structure all over the TO wafer with sidewalls of the template plug partially exposed and the top surface of the template plug completely exposed
2. Growing, by ELO, an unintentionally doped GaN layer (n-GaN) from the exposed GaN of the template plug along the top face of the Fabry-Perot filter structure to form a semiconductor base region which has a total width of about 30 to 50 micrometers in the third axial direction Ax3 perpendicular to the first and second axial directions Ax1 and Ax2
3. Performing the planarization of the semiconductor base region to form a planarized n-GaN layer
4. Growing, on the planarized n-GaN layer, a semiconductor laminate which includes device layers, e.g., an n-GaN for cladding and n-contacting, InGaN multiple quantum wells, an AlGaN electron blocking layer, and a p-GaN layer, and if needed a p⁺⁺ GaN layer
5. Polishing the back side of the TO wafer
6. Transferring a resist pattern, which is formed by reflow, by reactive ion etching to the back side of the TO wafer to form a monolithic micro lens
7. Producing a resist mask from a resist film covering the device layers through a backside exposure in which the monolithic micro lens is used to condense exposure light at a focal point which is positioned around the resist film
8. Forming a mask on the device layers using the resist mask
9. Conducting ion implantation with the mask to define an aperture structure
10. Depositing a transparent conductive oxide (TCO)
11. Producing a mesa structure in the semiconductor laminate
12. Depositing a passivation film of an omnidirectional reflector (ODR) material which has an opening at the top of the mesa structure
13. Depositing a dielectric distributed Bragg reflector laminate on the flat top of the device layers of the mesa structure
14. Depositing electrode metal pads on the semiconductor laminate that includes the mesa structure
15. Depositing a dielectric distributed Bragg reflector laminate on the curved surface of the TO substrate
16. Placing a bonding material on the backside of the TO substrate
17. Separating the TO wafer thus fabricated to form VCSEL chips
18. Bonding a VCSEL chip to a sub-mount

The VCSEL chip can be used in user-defined applications, such as a light source, sensor or both.

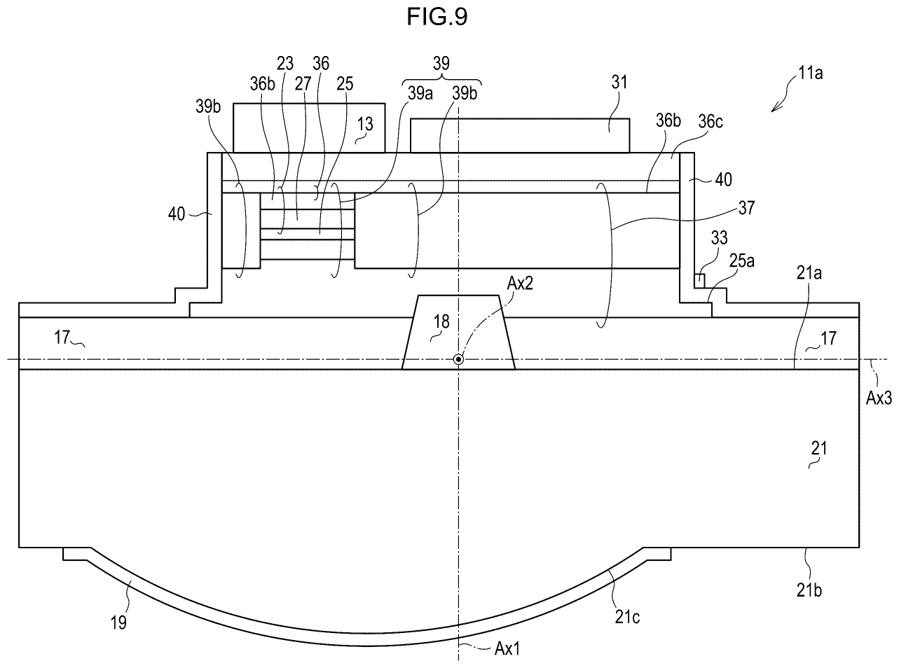

FIG. 9 is a schematic view showing a VCSEL according to another embodiment of the present disclosure. The VCSEL 11a is provided with the tunnel junction structure 36 and the aperture structure 39. The tunnel junction 36 forms an electrical route from the first electrode 31, which is located next to the first DBR mirror 13, to the conductive aperture portion 39a, which is located just below the first DBR mirror 13 and confines careers and lasing light. The tunnel junction structure 36 includes a p⁺⁺ III nitride layer 36a in the aperture structure 39, and an n⁺⁺ III nitride layer 36b on the mesa structure 36, and the p⁺⁺ III nitride layer 36a and the n⁺⁺ III nitride layer 36b make contact with each other to form a tunnel junction. This tunnel junction is embedded by an additional III nitride layer 36c.

A description will be given of an exemplary process flow in a method of fabricating the VCSEL 11a, which includes a heavily-doped n⁺⁺ layer and an n-type semiconductor layer, which works as a current spreading layer. The n⁺⁺ semiconductor layer makes contact with the topmost p⁺⁺ semiconductor layer to form the tunnel junction 36.

The method includes the following steps.
1. Preparing a starting base, where preparing the starting base includes forming a template plug of GaN, which runs straight on the TO wafer in the second axial direction Ax2 perpendicular to the first axial direction Ax1; and forming a dielectric Fabry-Perot filter structure all over the TO wafer with sidewalls of the template plug partially exposed and the top surface of the template plug completely exposed
2. Growing, by ELO, an unintentionally doped GaN layer (n-GaN) from the exposed GaN of the template plug along the top face of the Fabry-Perot filter structure to form a semiconductor base region which has a total width of around 30 to 50 micrometers in the third axial direction Ax3 perpendicular to the first and second axial directions Ax1 and Ax2
3. Performing the planarization of the semiconductor base region to form a planarized n-GaN layer
4. Growing, on the planarized n-GaN layer, a semiconductor laminate which include device layers, e.g., an n-GaN for cladding and n-contacting, InGaN multiple quantum wells, an AlGaN electron blocking layer, a p-GaN layer, and a p⁺⁺ GaN layer
5. Polishing the back side of the TO wafer
6. Transferring a resist pattern, which is formed by reflow, by reactive ion etching to the back side of the TO wafer to form a monolithic micro lens
7. Producing a resist mask on the device layers through a backside exposure in which the monolithic micro lens is used to condense exposure light at a focal point which is positioned around the resist film
8. Forming a mask on the device layers using the resist mask
9. Conducting ion implantation with the mask to define the aperture structure
10. After forming the aperture structure, re-growing an n⁺⁺ GaN layer to complete the tunnel junction, and further depositing, on the n⁺⁺ GaN layer, an n-GaN layer for contacting and current-spreading
11. Producing a mesa structure from the semiconductor laminate that includes the device layers and the tunnel junction
12. Depositing a passivation film of an omnidirectional reflector (ODR) material which has an opening for the contact area on the top face of the mesa structure
13. Depositing a dielectric distributed Bragg reflector laminate on the flat top of the device layers
14. Depositing electrode metal pads on the semiconductor laminate that includes the mesa structure
15. Depositing a dielectric distributed Bragg reflector laminate on the curved surface of the TO substrate
16. Placing a bonding material on the backside of the TO wafer
17. Separating the TO wafer thus fabricated to form VCSEL chips
18. Bonding a VCSEL chip to a sub-mount

The VCSEL chip can be used in user-defined applications, such as a light source, sensor or both.

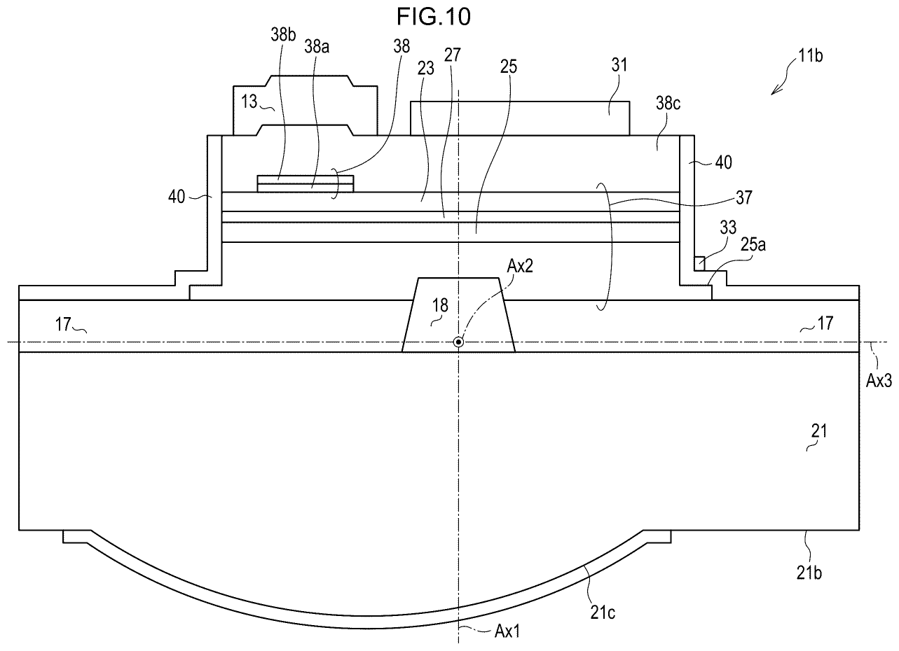

FIG. 10 is a schematic view showing a VCSEL according to still another embodiment of the present disclosure. The VCSEL 11b is provided with the buried tunnel junction structure 38 without the aperture structure 39. The buried tunnel junction 38 is located just below the first DBR mirror 13 to be aligned with the cavity, and is covered with a current spreading layer to define an electrical route from the first electrode 31, which is located next to the first DBR mirror 13, to the buried tunnel junction 38, which is used to confine careers and lasing light.

A description will be given of an exemplary process flow in a method for fabricating the VCSEL 11b, which includes the buried tunnel junction 38 including heavily-doped n⁺⁺ and p⁺⁺ semiconductor layers, and an n-type semiconductor layers which covers the buried tunnel junction structure 38 and works as the current spreading layer. The buried tunnel junction structure 38 includes a patterned p⁺⁺ III nitride layer 38a and a patterned n⁺⁺ III nitride layer 38b, which are disposed on the mesa structure 36. The p⁺⁺ III nitride layer 38a and the n⁺⁺ III nitride layer 38b make contact with each other to form a tunneling interface, and are embedded by an additional III nitride layer 38c. The additional III nitride layer 38c is grown on the mesa structure 37 so as to form the substantially planarized top surface thereof. The first electrode 31 is disposed in contact with the III nitride layer 38c, and the first DBR mirror 13 is disposed on the top of the III nitride layer 38c.

The method includes the following steps.
1. Preparing a starting base, where preparing the starting base includes forming a template plug of GaN, which runs straight on the TO wafer in the second axial direction Ax2 perpendicular to the first axial direction Ax1; and forming a dielectric Fabry-Perot filter structure all over the TO wafer with sidewalls of the template plug partially exposed and the top surface of the template plug completely exposed
2. Growing, by ELO, an unintentionally doped GaN layer (n-GaN) from the exposed GaN of the template plug along the top face of the Fabry-Perot filter structure to form a semiconductor base region which has a total width of around 30 to 50 micrometers in the third axial direction Ax3 perpendicular to the first and second axial directions Ax1 and Ax2
3. Performing the planarization of the semiconductor base region to form a planarized n-GaN layer
4. Growing, on the planarized n-GaN layer, a semiconductor laminate which includes device layers, e.g., an n-GaN for cladding and n-contacting, InGaN multiple quantum wells, an AlGaN electron blocking layer, a p-GaN layer, and a p⁺⁺ GaN layer
5. Polishing the back side of the TO wafer
6. Transferring a resist pattern, which is formed by reflow, by reactive ion etching to the back side of the TO wafer to form a monolithic micro lens
7. Re-growing an n⁺⁺ GaN layer on the p⁺⁺ GaN layer to complete a tunnel junction
8. Producing a resist mask from a resist film on the device layers through a backside exposure in which the monolithic micro lens is used to condense exposure light at a focal point which is located around the resist film
9. Patterning the tunnel junction with the resist mask to complete the buried tunnel junction on the device layers
10. After forming the buried tunnel junction, depositing an n-GaN layer which covers the buried tunnel junction to form the planarized n-GaN top face
11. Producing a mesa structure from the semiconductor laminate
12. Depositing a passivation film of an omnidirectional reflector (ODR) material which has an opening for the contact area on the mesa structure
13. Depositing a dielectric distributed Bragg reflector laminate on the flat top of the device layers
14. Depositing electrode metal pads on the semiconductor laminate that includes the mesa structure
15. Depositing a dielectric distributed Bragg reflector laminate on the curved surface of the TO substrate
16. Placing a bonding material on the backside of the TO wafer
17. Separating the TO wafer thus fabricated to form VCSEL chips
18. Bonding a VCSEL chip to a sub-mount

The VCSEL chip can be used in user-defined applications, such as a light source, sensor or both.

Furthermore, the fabrication of semiconductor chips in the background art certainly includes growing epitaxial device layers on the wafer; and dicing both of the device layers and the wafer. An area for dicing and chip singularization may need at least 10% of the processed area of the wafer.

There may be three approaches to fabricate a semiconductor chip, for example extended cavity VCSEL.

### Approach 1

First, whole device layers are epitaxially grown on a planar GaN substrate. After the growth, the GaN substrate is thinned by polishing at the backside thereof, and then a curved surface for the optical cavity, such as a micro lens, is formed on the polish backside.

### Approach 2

First, whole device layers are epitaxially grown on a planar GaN substrate. After the growth, the GaN substrate is removed to form a device laminate which include the device layers, and then the device laminate is bonded to a foreign substrate with a curved surface for the optical cavity, such as a micro lens, at the backside thereof.

### Approach 3

Approach 3 includes a fabrication flow in accordance with the present disclosure. As compared with approaches 1 and 2, the integration of an extended cavity in approach 3 is a simple step procedure without the removal and thinning of substrates. The dicing streets can be arranged between the semiconductor sections. The fabrication flow in accordance with the present disclosure allows various arrangements of device sections, for example, a high packing density of device sections on the wafer.

### EXAMPLES

### Transparent Oxide (TO) Substrate Material

The micro lens is integrated with the device layers on a TO substrate. The device layers are also grown on the TO substrate. The material of the TO substrate can encompass ZnO, Ga₂O₃, Al₂O₃, and other material transparent to infrared, visible, near-ultraviolet, and/or deep-ultraviolet wavelengths depending on the materials. The VCSEL device according to the present structure is provided with the cavity that is mainly dominated by the TO substrate of less absorption. This allows the fabrication of the VCSEL device to use a large-sized TO wafer, such as a sapphire wafer of more than 6 inches in size, which results in much more devices from a single run.

### Template Plug

Starting with a TO wafer on which a III nitride template plug is mounted, the height of the III nitride template plug can be 1 micrometer to 10 micrometers. Crystalline quality of a III nitride layer for the template plug increases with its thickness. Increasing the III nitride layer thickness can terminate threading dislocations therein, which are originated from the lattice mismatch at the substrate interface. Further, the larger thickness may provide the dielectric filter layer with a thick Fabry-Perot filter structure, which can be helpful in characterizing and forming a very narrow bandpass and better rejection regions outside the bandpass. The thicker Fabry-Perot filter embeds a lower sidewall portion of the template plug, which most of the defects may include.

For example, the template plugs may be strip-shaped parallel to <11-20> axis of hexagonal III nitride, such as GaN. In forming the template plugs, etching a III nitride film having a (0001)-polar orientation III nitride film provides the template plug strip thus formed with (11-22) sidewalls. Such a sidewall orientation can enhance the subsequent lateral growth therefrom. If needed, the III nitride template plug sidewall may be provided with another orientation that would enhance lateral growth. Alternatively, the template plug may be provided with a desired orientation which allows the enhanced growth of the III nitride layer along the dielectric filter layer.

### Fabry-Perot Filter/Antireflection

Using a Fabry-Perot filter structure is one of the desirable designs for the production of a narrow bandpass filter. A Fabry-Perot filter offers both the narrow bandpass and rejection bands on the both sides of the bandpass. The Fabry-Perot filter can be disposed inside the single lasing cavity, and includes a center spacer having a certain thickness, generally, a half of the lasing wavelength, and two identical reflector mirrors, identical to a DBR mirror structure, which sandwich the center spacer.

A typical all dielectric structure is as follows: “Substrate1/(HL)m/2nH/(LH)m/Substrate2”. Substrates 1 and 2 can be a GaN layer and a TO substrate, i.e., sapphire, respectively. “H” and “L” stand for respective layers with high and low refractive indices and their quarter wave optical thicknesses, and “m” and “n” are integers. The general thickness of the whole structure at an exemplary operating wavelength of 450 nm can be in a range of 1 to 2 micrometers or even thicker. The Fabry-Perot structure in the optimized design allows the very narrow bandpass, e.g., optical window “WIN”, around the central operating wavelength “λ0”, and may be provided with a thickness of above 2 micrometers. The “WIN” can be further narrowed by increasing the number of the dielectric layers and fine-tuning each layer thickness. The Fabry-Perot structure can be provided with a surface roughness of below one nanometer, and preferably, the roughness may be 0.1 to 1 nm in root-mean-square (RMS). The dielectric layers of the Fabry-Perot structure can be deposited by sputtering, atomic layer deposition, ion beam deposition, or the like. The Fabry-Perot filter comprises two reflectors and a high index material center layer. Each of the two reflectors includes alternately-deposited high and low refractive index materials, such as SiO₂ and HfO₂, each of which has a quarter-wave thickness. The high index material center layer has a thickness half of the central operating wavelength, and is disposed between these reflectors.

### Epitaxial Lateral Overgrowth

The III nitride template plugs arranged on the TO substrate can be shaped in the form of strips, and the lower sidewalls of the template plugs are embedded in a Fabry-Perot filter structure, which is made of all dielectric materials, such as SiO₂, Ta₂O₅, HfO₅ and the like, and the top faces of the template plugs are less defective. Preferably, the thickness of the plugs is designed to enable a thick Fabry-Perot filter which produces a very narrow bandpass spread “WIN”. The sidewalls of the plugs are exposed roughly 1 or 2 micrometers, and the top face width of the plugs is about 1 to 10 micrometers. The strips are arranged at a period of 50 to 200 micrometers. The strips can be provided with a length which matches that of the device section or may be much longer. The polar template plugs are provided with the top face orientation of c-face (0001), and accordingly, the strips of the template plugs may be oriented along <11-20> axis. Alternatively, the nonpolar template plugs are provided with the top face orientation of a-face (11-20) or m-face (1100), and accordingly, the strips of the template plugs are oriented along <0001> axis. Further, the semi-polar template plugs are provided with the top face orientation of (20-21) or (20-2-1) face, and accordingly, the strips of the template plugs are oriented along a direction parallel to [−1014] or [10-14], respectively. Other orientations may be use as well with the strips oriented in corresponding directions.

The TO wafer that mounts the template plugs with the sidewalls thereof partially exposed is loaded to a MOCVD reactor to grow III nitride islands. In one embodiment, the growth pressure ranges from 50 to 760 Torr, although the growth pressure preferably ranges from 100 to 300 Torr to provide an island-like III nitride semiconductor layer with a large width; the growth temperature ranges from 900 to 1200 degrees Celsius; the V/III ratio ranges from 10 to 30,000; the TMG flow ranges from 2 to 20 standard cubic centimeters per minute (sccm); the NH₃ flow ranges from 0.1 to 10 standard liter/min (slm); and only hydrogen gas, or both hydrogen and nitrogen gases are used as carrier gas. To obtain a smooth surface, the growth conditions of the III nitride islands can be optimized. Finally, a III nitride layer, e.g., the GaN layer 25, is grown by ELO to complete each island such that the GaN layer 25 has a thickness of about 1 to 10 micrometers and a width of 50 micrometers with the III nitride islands thus grown being spaced from each other by about 15 micrometers.

The TO wafer with the sidewalls of the template plugs partially exposed has a III nitride interface (exposed template plugs) and the dielectric interface (the Fabry-Perot filter layer) at the top thereof, and a ratio of these two interfaces is referred to as a “fill factor”. In the reactor, III nitride can be deposited on the III nitride interface and cannot be deposited on the dielectric interface, which is represented in terms of the “fill factor”. In the present TO wafer, the fill factor is lower than 1. The deposition in which the fill factor deviates from 1 may cause III nitride atoms in the reactor to accumulate more at the margin of growing face due to the abundance of III nitride atoms, which occurs around a boundary between the growth and non-growth interfaces, and accordingly, it is likely that a thicker GaN layer is produced at the margin of the III nitride island as compared to the center region thereof.

### Polishing

Due to the abundance of III nitride atoms, III nitride islands grown from the respective template plugs may have a concave shape at the top thereof. In order to obtain planar device layers, the III nitride islands are grown initially to a thickness of 5 to 10 micrometers, and then are planarized by polishing or etching to form a III nitride base with a flat top face. On this flat top face, device layers comprising p-GaN, n-GaN, InGaN and AlGaN layers are regrown. Specifically, since the device layers including n-GaN, MQW, and p-GaN, and/or tunnel junction layers all together may not exceed 700 nm in thickness, in this regrowth, edge growth which is caused by the abundance of III nitride atoms may be negligibly small.

### Device Layers Growth

The III nitride based semiconductor layers, and tunnel junction or buried tunnel junction layers are regrown on the polished face of the III nitride base. The semiconductor laminate and the semiconductor section 15 each include semiconductor device layers of III nitride compound which can include In, Al and/or B, as well as dopants or impurities, such as Mg, Si, Zn, O, C, and H. The device layers of III nitride based semiconductor generally comprise more than three layers, including an n-type layer, an undoped layer, and a p-type layer. The device layers specifically comprise gallium nitride based material, such as a GaN layer, an AlGaN layer, an InGaN layer, and an AlGaInN layer. For example, the epitaxial growth of these device layers is carried out in an MOCVD or MBE reactor. The device region comprises a thick n-GaN layer, a multiple quantum wells (for example, MQW of 3 nm-thick wells and 7 nm-thick barriers), a 10 nm-thick p-AlGaN electron-blocking layer (EBL), a 100 nm-thick p-GaN layer, and a 10 nm-thick p⁺⁺GaN layer.

When ITO is employed as a current spreading layer, the topmost device layer may be p⁺⁺GaN. Otherwise, an additional 10 nm thick n⁺⁺GaN layer is deposited on the top of p⁺⁺GaN for the tunnel structure. For the buried tunnel junction and tunnel junction designs, a current spreading layer of 50 nm-thick n-GaN layer is deposited over the additional n⁺⁺GaN layer.

Specifically, in the tunnel junction design, the growth of the semiconductor laminate is stopped after growing the p⁺⁺GaN layer, then the ion-implantation is conducted to form the aperture structure, and thereafter the n⁺⁺GaN layer and n-type GaN layers are deposited on the aperture structure.

Specifically, in the buried tunnel junction design, the growth of the semiconductor laminate is stopped after growing the n⁺⁺GaN layer over the p⁺⁺GaN layer, then the n⁺⁺GaN and p⁺⁺GaN layers are patterned to form a patterned tunnel junction, and thereafter the n-type GaN layer is deposited on the patterned tunnel junction. The regrowth can be either carried out using an MOCVD or MBE (molecular beam epitaxy) reactor. Using MBE instead of MOCVD can eliminate hydrogen re-passivation of p-GaN during the tunnel junction regrowth.

Alternatively, the present design described in the embodiments may include processing the island-like III nitride device layers. In order to recover hydrogen re-passivation, activation of p-type gallium nitride base material, such as p-GaN, can be achieved through lateral diffusion, and the p-GaN layer, which is embedded by the tunnel junction or current spreading layer (n-GaN), can be activated. Accordingly, the design of the particular device layers can choose MBE or MOCVD depending on the manufacturing parameters, such as cost and yield.

### Micro Lens Formation

The monolithic micro lens is used in the aperture fabrication procedure, and in particular, the monolithic lens at the backside can condense exposure light at the location of the aperture structure through a lensing effect of the curved surface, which is used to form the curved second DBR mirror in the VCSEL product.

The TO substrate can be a double side polished substrate, and accordingly, the micro lens pattern on the back surface is positioned such that the resulting location and shape of the lens can be useful in being accurately aligned with the location of the aperture portion at the top face of the semiconductor section. The monolithic micro lens is fabricated through photoresist (PR) re-flow and dry etching processes. For example, a double side polished sapphire substrate may be (0001)-oriented 2-in wafers, and if possible, a larger diameter wafer may be used as well. Specifically, an array of circular PR disks is patterned on the back side of the polished sapphire substrate by standard photolithographic technique. The PR patterns are then baked with a hot plate at an elevated temperature. After reaching the transition temperature of PR, the PR patterns start to reflow to form a convex shape with the center of each pattern being the thickest. Then, the convex shape is transferred to the sapphire substrate, for example, with an inductively coupled plasma (ICP) system. Optimized etching conditions can achieve surface roughness below one nanometer, and preferably, the etched surface of the sapphire can have a surface roughness between 0.1 nm to 0.5 nm to avoid optical scattering and the corresponding optical loss.

### Ion Implantation

Ion implantation is used to form an electrical, optical aperture in the GaN-based layers by damaging these GaN-based layers outside the aperture, and damaged GaN-based material is no longer conductive. This method can keep the top face planar and can create a very slight index guiding between the aperture region and the damaged region. The damaged region can have a higher absorption value than that of the un-implanted material of the aperture region, and can be, however, provided with an increased optical loss in the cavity. Heavy ions, such as aluminum (Al), boron (B), and the like, can be used for ion implantation procedure. The basic idea of the ion implantation is to create a conducting aperture.

### Transparent Conductive Layer

After the ion implantation, the transparent conducting layer can be laminated over the device layers, or the regrowth of III nitride for the tunnel junction is performed on the device layers with or without ion implantation process. ITO can be used as a commonly-used transparent current spreading layer. The inclusion of ITO to the VCSEL may cause an additional absorption, but this absorption can be decreased by making the intensity of the electro-magnetic wave low around the ITO layer. Alternative approaches, such as tunnel junctions, can also be used to spread current and make the optical absorption low.

### Tunnel Junction

The tunnel junction approach allows hole careers to be injected into the active layer of the device via an n-type semiconductor because the junction between a highly-doped n-type region and a highly doped p-type region allows electrons to tunnel from the valence band of the p-type region to the conduction band of the n-type region under a reverse bias, thereby causing change in the type of conducting careers. As the tunneling probability depends exponentially on the tunneling distance, the highly doped regions are preferred (˜10¹⁹/cm³ or above) to produce a thin depletion width for efficient operation. After forming the aperture structure by ion implantation, n⁺⁺/n-GaN layers (10/50 nm in thickness) are epitaxially regrown on the topmost p⁺⁺GaN layer of the device layers to form the tunnel junction and the current spreading layer.

### Buried Tunnel Junction

The buried tunnel junction can work as not only a career-type changer but also a current aperture, and is formed by growing a planar tunnel junction of highly doped p⁺⁺/n⁺⁺ layers (10/10 nm in thickness); forming, at a desired aperture position, a mask on the highly doped junction layers using the micro lens of the TO substrate; and etching the highly doped junction layers with the mask. The buried tunnel junction is not always combined with the current aperture, which is formed by ion implantation, and if needed, may be combined with the current aperture.

### DBR Mirror

The present DBR mirrors each include alternating dielectric layers joined together to form a reflective mirror, and are disposed on top and bottom of the VCSEL to form the optical cavity. The dielectric DBR mirrors may include, for example, dielectric quarter wavelength-thick SiO₂/Ta₂O₅ layers. The number of pairs is associated with its reflectance, and the reflectance of the DBR mirror on the p-side of the VCSEL may be smaller than that on the curved surface to promote light emission.

### Omnidirectional Reflector (ODR)

The ODR is disposed outside the optical cavity, and can reflect light that leaks out of the propagation path. The ODR is also disposed between the anode and cathode electrodes, and acts as to protect and/or passivate the device layers from possible contaminants and direct contacts.

### Metal Pads

Metals, such as gold (Au), aluminum (AI), nickel (Ni), palladium (Pd), titanium (Ti), Indium (In) and the like, can be used as material of metal pads in the fabrications of the VCSEL. The metal layer can be formed by sputtering, evaporating, or plating.

### Applications

### Data Centers

The requirements for data communications with increased cloud computing and streaming services increase demand for information transfer hardware, such as edge emitting lasers and VCSELs, which provide servers with server data transfer in data centers. In most of the data communications, the VCSELs operate at infrared (IR) wavelengths. The III nitride VCSEL according to the aforementioned embodiments can be used in data communications associated with the data centers.

### Lighting

GaN-based light sources, such as LEDs, have led to a dramatic shift in residential and automotive lighting. Lighting in combination with communication services is very desirable in the future smart city and smart infrastructure. VCSELs may be better alternatives to LEDs and edge emitting laser diodes. The procedures developed in the aforementioned embodiments can be used to manufacture VCSEL units that are applicable in lighting applications.

### Visible Light Communications

Laser light can be used for data transfer and communication applications through light fidelity (LiFi). With the rapid increase of IoT devices, demands on data transmission continue to expand. The RF spectrum is getting saturated, and new frequencies are needed to keep up with the continuously growing demands. The adoption of GaN-based VCSELs into existing LED architectures is simpler than replacing them with edge emitting lasers. The III nitride VCSEL according to the aforementioned embodiments can be adopted in visible light communications.

### Near Eye Displays

Near eye displays will represent the next major wave in consumer electronics, and are the basis of virtual reality (VR) and augmented reality (AR) technologies. Currently, micro-LEDs are predominant choice for displays, and however, despite the limited progress in the current VCSEL research, VCSELs may be introduced as miniature displays and near eye displays. The VCSELs can provide relatively low optical power, which is beneficial in maintaining eye safety, and low divergence and circular symmetry, which can reduce the number of additional optical elements, thus leading to compactness of the device. The 2D array integration of VCSELs is simpler than that of edge emitting lasers. The III nitride VCSEL according to the aforementioned embodiments can be applied in these applications.

Advantageous effects according to the aforementioned embodiments are as follows:
Use of a sufficiently long cavity without excessive diffraction loss, with the two reflective mirrors defining the VCSEL cavity, and the Fabry-Perot filter added to narrow down to single mode operation;
Better thermal management due to a long-enough cavity and/or electrical contact placement on the III nitride layers;
Better thermal conduction of the device by the GaN template plugs that connect with the TO substrate, thereby improving thermal performance;
Use of less-costly large-sized template substrates, such as GaN on Sapphire;
Minimizing semiconductor layer wastage by use of the island-like III nitride;
Eliminating substrate removal and bonding procedures in the fabrication, thus improving production parameters; and
Unlocking the usage of foreign substrates in the production of VCSELs by use of ELO technique

The aforementioned embodiments are expected to provide a significant improvement in the performance and reduction in the manufacturing cost and eliminating complex procedures.

The aforementioned embodiments propose the Fabry-Perot filter integration in the VCSEL, which enables epitaxial lateral overgrowth to improve crystalline quality of the device layers.

Using a template TO material substrate which includes a structure similar to GaN/Sapphire allows the device layers to be grown on the epitaxial lateral overgrown wing, which provides, in general, defect free or fewer defects, thus leading to high crystalline quality.

### Aspect 1

A VCSEL comprises: an oxide substrate having a first face and a second face at an opposite side from the first face, the second face including a curved surface; a semiconductor section disposed on the first face of the oxide substrate; a dielectric filter layer disposed between the semiconductor section and the first face of the oxide substrate and having a reflective spectrum, the reflective spectrum being configured to provide an optical window; a first distributed Bragg reflector (DBR) mirror, the semiconductor section being disposed between the dielectric filter layer and the first DBR mirror; and a second DBR mirror disposed at the curved surface of the oxide substrate, the first DBR mirror, the semiconductor section, the dielectric filter layer, the oxide substrate, and the second DBR mirror being arranged in a first axial direction to form an extended cavity, the semiconductor section including a p-type III nitride region, a III nitride region, and a III nitride active region between the p-type III nitride region and the III nitride region, the p-type III nitride region, the III nitride active region, and the III nitride region being arranged in the first axial direction, and the III nitride region including an n-type III nitride region.

### Aspect 2

In the VCSEL according to the aspect 1, the dielectric filter layer has a through hole extending in the first axial direction. The VCSEL further comprises a III nitride template plug disposed in the through hole and extending from the first face of the oxide substrate to the semiconductor section in the through hole.

### Aspect 3

In the VCSEL according to aspect 2, the III nitride template plug comprises an embedded portion in the through hole and a projection protruding into the semiconductor section, and the embedded portion of the III nitride template plug is disposed in contact with the first face of the oxide substrate.

### Aspect 4

In the VCSEL according to any one of aspects 1 to 3, the curved surface of the oxide substrate has a center line, and the III nitride template plug and the center line of the curved surface are misaligned with each other.

### Aspect 5

In the VCSEL according to any one of aspects 1 to 4, a length of the extended cavity is more than 50 micrometers.

### Aspect 6

In the VCSEL according to any one of aspects 1 to 5, the curved surface has a radius of curvature that is more than 50 micrometers.

### Aspect 7

In the VCSEL according to any one of aspects 1 to 6, the second DBR mirror is curved, and the first DBR mirror is planar, and a distance between the first and second DBR mirrors is more than 50 micrometers.

### Aspect 8

In the VCSEL according to any one of aspects 1 to 7, the semiconductor section includes a mesa structure, and the mesa structure includes a base region and a mesa region disposed on the base region. The VCSEL further comprises: a conductive layer disposed on the semiconductor section, a part of the conductive layer being disposed between the first DBR mirror and the semiconductor section; a first electrode disposed on the conductive layer outside the DBR mirror, the first electrode being disposed in contact with the conductive layer; and a second electrode disposed at a face of the base region of the mesa structure.

### Aspect 9

In the VCSEL according to aspect 8, the semiconductor section has a first face and a second face at an opposite side from the first face of the semiconductor section, the dielectric filter layer is disposed at the first face of the semiconductor section, and the conductive layer is disposed at the second face of the semiconductor section.

### Aspect 10

In the VCSEL according to any one of aspects 1 to 9, the semiconductor section includes an aperture structure, the aperture structure including an aperture region extending in the first axial direction, and an isolation region surrounding the aperture region, and the first DBR mirror, the aperture region, and the second DBR mirror are arranged along an axis that does not pass through the III nitride template plug.

### Aspect 11

In the VCSEL according to any one of aspects 1 to 10, a total thickness of the semiconductor section is more than 0.5 micrometers.

### Aspect 12

In the VCSEL according to any one of aspects 1 to 11, the dielectric filter layer includes a Fabry-Perot filter configured to provide the reflective spectrum for the optical window.

### Aspect 13

In the VCSEL according to any one of aspects 1 to 12, the oxide substrate includes one of aluminum oxide, zinc oxide, or gallium oxide.

### Aspect 14

In the VCSEL according to any one of aspects 1 to 13, the first DBR mirror has a lower reflectance than that of the second DBR mirror.

### Aspect 15

In the VCSEL according to any one of aspects 1 to 14, the III nitride active region comprises a quantum well structure configured to generate light having a wavelength in a first reflection spectrum of the first DBR mirror, a second reflection spectrum of the second DBR mirror, and the optical window of the dielectric filter layer.

### Aspect 16

A method for fabricating a VCSEL comprises: preparing a starting base, the starting base including an oxide base, a III nitride template plug, and a dielectric filter layer, the oxide base having a first face and a second face at an opposite side from the first face of the oxide base, the dielectric filter layer and the III nitride template plug being located on the first face of the oxide base, the dielectric filter layer having a reflective spectrum, and the reflective spectrum being configured to provide an optical window; growing a III nitride region from the III nitride template plug on the dielectric filter layer; after growing the III nitride region, growing a semiconductor laminate including an n-type III nitride region, a III nitride active region, and a p-type III nitride region; processing the oxide base at the second face thereof to form an oxide substrate having a curved surface, the curved surface being disposed at an opposite side from a first face of the oxide substrate; after growing the semiconductor laminate, forming a first distributed Bragg reflector (DBR) laminate on the first face of the oxide substrate; and forming a second DBR laminate on the curved surface of the oxide substrate.

### Aspect 17

The method according to aspect 16 further comprises, prior to growing the semiconductor laminate, planarizing the III nitride region by at least one of polishing or etching.

### Aspect 18

The method according to aspect 16 or 17 further comprises, after growing the semiconductor laminate and prior to forming the first DBR laminate, depositing a conductive layer on the first face of the oxide substrate; and forming a first electrode on the conductive layer.

### Aspect 19

The method according to any one of aspects 16 to 18 further comprises producing a mesa structure from the semiconductor laminate by etching to form an etched face of the n-type III nitride region, the mesa structure including the III nitride active region;

### Aspect 20

The method according to aspect 19 further comprises forming a second electrode on the etched face of the n-type III nitride region outside the mesa structure.

### Aspect 21

In the method according to any one of aspects 16 to 20, the semiconductor laminate further includes one of a tunnel junction or a buried tunnel junction.

### Aspect 22

In the method according to any one of aspects 16 to 21, the oxide substrate includes one of aluminum oxide, zinc oxide, or gallium oxide.

### Aspect 23

In the method according to any one of aspects 16 to 22, preparing a starting base comprises: depositing a III nitride layer on the first face of the oxide base; patterning the III nitride layer to form the III nitride template plug; depositing multiple dielectric layers to cover the first face of the oxide base and the III nitride template plug; and processing the multiple layers to form the dielectric filter layer such that the III nitride template plug is located in a through hole of the dielectric filter layer, and the III nitride template plug has a height that is greater than a thickness of the dielectric filter layer.

### Aspect 24

In the method according to aspect 23, the multiple dielectric layers are grown to form a Fabry-Perot filter configured to provide the reflective spectrum for the optical window.

### Aspect 25

In the method according to any one of aspects 16 to 24, the III nitride region is grown from the III nitride template plug by epitaxial lateral overgrowth to form a III nitride island.

### Aspect 26

In the method according to aspect 25, the III nitride island extends along a top face of the dielectric filter layer from the III nitride template plug outward, and the top face of the dielectric filter layer has a roughness lower than one nanometer.

### Aspect 27

In the method according to any one of aspects 16 to 26, the III nitride active region is grown to form a quantum well structure configured to generate light having a wavelength in a first reflection spectrum of the first DBR laminate, a second reflection spectrum of the second DBR laminate, and the optical window of the dielectric filter layer.

### Aspect 28

In the method according to any one of aspects 16 to 27, processing the oxide base at the second face thereof to form an oxide substrate comprises: forming a patterned resist layer on the second face of the oxide base; thermally treating the patterned resist layer to form a convex resist region; and transferring a shape of the convex resist region to the oxide base by etching the convex resist region and the oxide base to form the curved surface. Etching the convex resist region and the oxide substrate is stopped so as to satisfy a condition that, and after forming the first DBR laminate and the second DBR laminate, a distance between the second DBR laminate and the first DBR laminate is more than 50 micrometers.

### Aspect 29

In the method according to any one of aspects 16 to 28, the curved surface has a radius of curvature which is more than 50 micrometers.

### Aspect 30

The method according to any one of aspects 16 to 29 further comprises: after growing the semiconductor laminate and prior to forming the conductive layer, forming a resist film on the first face of the oxide substrate; illuminating the resist layer through the curved surface of the oxide substrate to produce a patterned mask from the resist film; and performing ion implantation with the patterned mask to form an aperture structure including an aperture region and an isolation region surrounding the aperture region.

Having described and illustrated the principle of the invention in a preferred embodiment thereof, it is appreciated by those having skill in the art that the invention can be modified in arrangement and detail without departing from such principles. We therefore claim all modifications and variations coming within the spirit and scope of the following claims.

### REFERENCE SIGNS LIST

11, 11a, 11b, 11c VCSEL
13, 19 distributed Bragg reflector (DBR)
15 semiconductor section
17 dielectric filter layer
23 p-type III nitride region
25 n-type III nitride region
27 III nitride active region
CAV optical cavity
31 anode electrode
33 cathode electrode
35 conductive layer
37 mesa structure
Ax1, Ax2, Ax3 axial direction

1. A vertical cavity surface emitting laser (VCSEL), comprising:
an oxide substrate having a first face and a second face at an opposite side from the first face, the second face including a curved surface;
a semiconductor section disposed on the first face of the oxide substrate;
a dielectric filter layer disposed between the semiconductor section and the first face of the oxide substrate and having a reflective spectrum, the reflective spectrum being configured to provide an optical window;
a first distributed Bragg reflector (DBR) mirror, the semiconductor section being disposed between the dielectric filter layer and the first DBR mirror; and
a second DBR mirror disposed at the curved surface of the oxide substrate, the first DBR mirror, the semiconductor section, the dielectric filter layer, the oxide substrate, and the second DBR mirror being arranged in a first axial direction to form an extended cavity,
the semiconductor section including a p-type III nitride region, a III nitride region, and a III nitride active region between the p-type III nitride region and the III nitride region, the p-type III nitride region, the III nitride active region, and the III nitride region being arranged in the first axial direction, and the III nitride region including an n-type III nitride region.

2. The VCSEL according to claim 1,
wherein the dielectric filter layer has a through hole extending in the first axial direction,
the VCSEL further comprising a III nitride template plug disposed in the through hole and extending from the first face of the oxide substrate to the semiconductor section in the through hole.

3. The VCSEL according to claim 2,
wherein the III nitride template plug comprises an embedded portion in the through hole and a projection protruding into the semiconductor section, and the embedded portion of the III nitride template plug is disposed in contact with the first face of the oxide substrate.

4. The VCSEL according to claim 2,
wherein the curved surface of the oxide substrate has a center line, and the III nitride template plug and the center line of the curved surface are misaligned with each other.

5. The VCSEL according to claim 1,
wherein a length of the extended cavity is more than 50 micrometers.

6. The VCSEL according to claim 1,
wherein the curved surface has a radius of curvature that is more than 50 micrometers.

7. The VCSEL according to claim 1,
wherein the second DBR mirror is curved, and the first DBR mirror is planar, and a distance between the first and second DBR mirrors is more than 50 micrometers.

8. The VCSEL according to claim 1,
wherein the semiconductor section includes a mesa structure, and the mesa structure includes a base region and a mesa region disposed on the base region,
the VCSEL further comprising:
a conductive layer disposed on the semiconductor section, a part of the conductive layer being disposed between the first DBR mirror and the semiconductor section;
a first electrode disposed on the conductive layer outside the DBR mirror, the first electrode being disposed in contact with the conductive layer; and
a second electrode disposed at a face of the base region of the mesa structure.

9. The VCSEL according to claim 8,
wherein the semiconductor section has a first face and a second face at an opposite side from the first face of the semiconductor section, the dielectric filter layer is disposed at the first face of the semiconductor section, and the conductive layer is disposed at the second face of the semiconductor section.

10. The VCSEL according to claim 2,
wherein the semiconductor section includes an aperture structure, the aperture structure includes an aperture region extending in the first axial direction, and an isolation region surrounding the aperture region, and the first DBR mirror, the aperture region, and the second DBR mirror are arranged along an axis that does not pass through the III nitride template plug.

11. The VCSEL according to claim 1,
wherein a total thickness of the semiconductor section is more than 0.5 micrometers.

12. The VCSEL according to claim 1,
wherein the dielectric filter layer includes a Fabry-Perot filter configured to provide the reflective spectrum for the optical window.

13. The VCSEL according to claim 1,
wherein the oxide substrate includes one of aluminum oxide, zinc oxide, or gallium oxide.

14. The VCSEL according to claim 1,
wherein the first DBR mirror has a lower reflectance than that of the second DBR mirror.

15. The VCSEL according to claim 1,
wherein the III nitride active region comprises a quantum well structure configured to generate light having a wavelength in a first reflection spectrum of the first DBR mirror, a second reflection spectrum of the second DBR mirror, and the optical window of the dielectric filter layer.

16. A method for fabricating a vertical cavity surface emitting laser (VCSEL), the method comprising:
preparing a starting base, the starting base including an oxide base, a III nitride template plug, and a dielectric filter layer, the oxide base having a first face and a second face at an opposite side from the first face of the oxide base, the dielectric filter layer and the III nitride template plug being located on the first face of the oxide base, the dielectric filter layer having a reflective spectrum, and the reflective spectrum being configured to provide an optical window;
growing a III nitride region from the III nitride template plug on the dielectric filter layer;
after growing the III nitride region, growing a semiconductor laminate including an n-type III nitride region, a III nitride active region, and a p-type III nitride region;
processing the oxide base at the second face thereof to form an oxide substrate having a curved surface, the curved surface being disposed at an opposite side from a first face of the oxide substrate;
after growing the semiconductor laminate, forming a first distributed Bragg reflector (DBR) laminate on the first face of the oxide substrate; and
forming a second DBR laminate on the curved surface of the oxide substrate.

17. The method according to claim 16, further comprising, prior to growing the semiconductor laminate, planarizing the III nitride region by at least one of polishing or etching.

18. The method according to claim 16, further comprising, after growing the semiconductor laminate and prior to forming the first DBR laminate, depositing a conductive layer on the first face of the oxide substrate; and
forming a first electrode on the conductive layer.

19. The method according to claim 16, further comprising producing a mesa structure from the semiconductor laminate by etching to form an etched face of the n-type III nitride region, the mesa structure including the III nitride active region.

20. The method according to claim 19, further comprising forming a second electrode on the etched face of the n-type III nitride region outside the mesa structure.

21. The method according to claim 16,
wherein the semiconductor laminate further includes one of a tunnel junction or a buried tunnel junction.

22. The method according to claim 16,
wherein the oxide substrate includes one of aluminum oxide, zinc oxide, or gallium oxide.

23. The method according to claim 16,
wherein preparing a starting base comprises: depositing a III nitride layer on the first face of the oxide base; patterning the III nitride layer to form the III nitride template plug; depositing multiple dielectric layers to cover the first face of the oxide base and the III nitride template plug; and processing the multiple layers to form the dielectric filter layer such that the III nitride template plug is located in a through hole of the dielectric filter layer, and the III nitride template plug has a height that is greater than a thickness of the dielectric filter layer.

24. The method according to claim 23,
wherein the multiple dielectric layers are grown to form a Fabry-Perot filter configured to provide the reflective spectrum for the optical window.

25. The method according to claim 16,
wherein the III nitride region is grown from the III nitride template plug by epitaxial lateral overgrowth to form a III nitride island.

26. The method according to claim 25,
wherein the III nitride island extends along a top face of the dielectric filter layer from the III nitride template plug outward, and the top face of the dielectric filter layer has a roughness lower than one nanometer.

27. The method according to claim 16,
wherein the III nitride active region is grown to form a quantum well structure configured to generate light having a wavelength in a first reflection spectrum of the first DBR laminate, a second reflection spectrum of the second DBR laminate, and the optical window of the dielectric filter layer.

28. The method according to claim 16,
wherein processing the oxide base at the second face thereof to form an oxide substrate comprises forming a patterned resist layer on the second face of the oxide base, thermally treating the patterned resist layer to form a convex resist region, and transferring a shape of the convex resist region to the oxide base by etching the convex resist region and the oxide base to form the curved surface, and
wherein etching the convex resist region and the oxide substrate is stopped so as to satisfy a condition that, after forming the first DBR laminate and the second DBR laminate, a distance between the second DBR laminate and the first DBR laminate is more than 50 micrometers.

29. The method according to claim 16,
wherein the curved surface has a radius of curvature which is more than 50 micrometers.

30. The method according to claim 18, further comprising:
after growing the semiconductor laminate, forming a resist film on the first face of the oxide substrate;
illuminating the resist layer through the curved surface of the oxide substrate to produce a patterned mask from the resist film; and
performing ion implantation with the patterned mask to form an aperture structure including an aperture region and an isolation region surrounding the aperture region.
